(19) United States
(12) Patent Application Publication
(10) Pub. No.: US 2001/0040451 A1
(43) Pub. Date: Nov. 15, 2001

(54) CONTACT PROBE FOR TESTING LIQUID CRYSTAL DISPLAY AND LIQUID CRYSTAL DISPLAY TESTING DEVICE HAVING THEREOF

(76) Inventors: HIDEAKI YOSHIDA, SANDA-SHI (JP); TOSHINORI ISHII, SANDA-SHI (JP); ATUSHI MATSUDA, SANDA-SHI (JP); MITSUYOSHI UEKI, SANDA-SHI (JP); TADASHI NAKAMURA, SANDA-SHI (JP); NAOKI KATO, JAPAN (JP)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(21) Appl. No.: 08/880,524

(22) Filed: Jun. 23, 1997

(30) Foreign Application Priority Data
Jun. 28, 1996 (JP) 8-169701
Jul. 2, 1996 (JP) 8-172425
Aug. 9, 1996 (JP) 8-211283
Feb. 27, 1997 (JP) 9-44426

(51) Int. Cl. G01R 31/00

(52) U.S. Cl. 324/300

(57) ABSTRACT

A contact probe for carrying out an electric test by being brought into contact with respective terminals of a liquid crystal display device and a liquid crystal display testing device utilizing such a contact probe. The contact probe has a structure which may include a metal film attached to a nonconductive resin film, which prevents intervals between contact pins from being changed, for example based on changes in humidity. A nonconductive resin film may also be attached on the metal film. An elastic film may also be attached to a nonconductive resin film to ensure a proper orientation of contact pins in a testing operation. The liquid crystal display testing device can utilize such contact probes.

### BACKGROUND OF THE INVENTION

1. Field of the Invention

The present invention relates to a contact probe for carrying out an electric test by being brought into contact with respective terminals of a liquid crystal display, and further the present invention relates to a liquid crystal display testing device having the contact probe.

2. Discussion of the Background Art

It has been known that a contact probe is used for carrying out an electric test of a liquid crystal display. As shown by a perspective view of FIG. 27, such a contact probe is provided with a constitution in which contact pins 4 arranged in parallel, which are constructed of a metal of Ni (nickel) or a Ni alloy plated with Au (gold), are attached on one face of a nonconductive resin film 5 of, for example, a polyimide resin film or the like, orthogonally to a longitudinal direction of the nonconductive resin film 5. Portions of the contact pins 4 are projected from end portions of the nonconductive resin film 5. FIG. 28 shows a sectional view taken from a line A-A of the contact probe 10 in FIG. 27.

A further specific explanation will be given of a method of setting the contact probe 10 to a jig for carrying out an electric test of a liquid crystal display by using the contact probe 10 with reference to FIG. 29 through FIG. 32. FIG. 29 is a disassembled perspective view of a jig for setting the contact probe 10. The jig includes a top clamp 7 and a bottom clamp 8. The top clamp 7 is provided with a first projection 9 for holding the nonconductive resin film 5 on a side of front ends of the contact pins 4, a second projection 13 for holding terminals 12 on a side of a TABIC 11 and a third projection 14 for holding the TABIC 11 per se. Further, with respect to the bottom clamp 8, an inclined plate 15 and an attaching plate 16 are attached on a bottom plate 17.

The contact probe 10 is mounted on the inclined plate 15, and the terminals 12 on the side of the TABIC 11 are mounted to be disposed between portions of the nonconductive resin film 5 of the contact probe 10. Thereafter, the top clamp 7 is mounted such that the first projection 9 of the top clamp 7 is brought into contact with the nonconductive resin film 5 on the side of the front ends of the contact pins 4 and the second projection 13 is brought into contact with the terminals 12 on the side of the TABIC 11, respectively, and the top clamp 7 is attached by bolts 18 as illustrated in FIG. 30. FIG. 30 is a perspective view showing a state in which the contact probe 10 is attached to the jig by the bolts 18.

Next, as shown in FIG. 31, the jig attached with the contact probe 10 is attached to a frame 19 in a shape of a picture frame. At this moment, the contact pins 4 of the contact probe 10 are kept in an inclined state, and therefore the contact pins 4 projecting from a front end of the contact probe 10 are pressed to terminals (not shown) of a liquid crystal display 20.

FIG. 32 is a sectional view taken from a line B-B of FIG. 31 in a state in which the jig for the contact probe 10 is attached to the frame 19 in a shape of a picture frame by bolts 18′. Signals obtained from the contact pins 4 can be transmitted externally via the TABIC 11 in a state in which the front ends of the contact pins 4 are brought into contact with terminals (not shown) of the liquid crystal display 20.

The above-described background contact probe 10 is provided with a structure in which the contact pins 4 constructed of a metal of Ni or a Ni alloy plated with Au are attached on one face of the nonconductive resin film 5 including polyimide resin as shown in FIG. 27 and FIG. 28. However, an elongation is caused in the nonconductive resin film 5 including polyimide resin by absorbing moisture, and therefore according to the background contact probe 10, as shown in FIG. 33 which is a front view viewing from a D direction of FIG. 27, intervals t between the contact pins 4 are changed. This results in that the front end portions of the contact pins 4 cannot be accurately brought into contact with predetermined positions of terminals of the liquid crystal display 20, and thereby an accurate electric test may not be carried out.

As shown in a sectional view of FIG. 34, in respect of a front end portion of the contact pin 4 of the background contact probe 10, a front end S1 bent upwardly and a front end S2 bent downwardly may result instead of a normal front end S. As shown in a sectional view of FIG. 35, even if the contact pins 4 of the contact probe 10 having the bent front end S1 and the bent front end S2 are pinched by the first projection 9 of the top clamp 7 and the inclined plate 15 and the contact pins 4 are pressed onto the liquid crystal display 20, the normal front end S and the front end S2 bent downwardly are brought into contact with terminals of the liquid crystal display 20. However, with respect to the front end S1 bent upwardly, a sufficient contact pressure may not be obtained even if the front end S2 is brought into contact with the terminals with the result that contact failure of the contact pins 4 in respect of the liquid crystal display 20 may occur, and thereby an accurate electric measurement may not be conducted.

Further, an amount of pressing the contact pins 4 is increased or decreased to obtain a desired contact pressure in testing. Although a large amount of pressing is needed to obtain a large contact pressure, the amount of pressing is limited due to a shape of a needle, whereby the large contact pressure may not be obtained.

### SUMMARY OF THE INVENTION

It is a first object of the present invention to provide a novel contact probe in which intervals between contact pins are not changed even with a change in humidity and front end portions of the contact pins can be accurately brought into contact with predetermined positions of terminals of a liquid crystal display, whereby an accurate electric test can be carried out.

It is a second object of the present invention to provide a contact probe which is brought into contact with terminals of a liquid crystal display, in which a uniform contact pressure is provided to the respective pins and which is capable of eliminating measurement failure caused by the contact failure and capable of obtaining a necessary contact pressure even with contact pins bent upwardly.

The present invention includes a feature that in respect to a contact probe for testing a liquid crystal display in which contact pins arranged in parallel are attached on one face of a nonconductive resin film such that the contact pins are orthogonal to the nonconductive resin film and front end portions of the contact pins are projected from the nonconductive resin film, a metal film is attached on the nonconductive resin film. As a further feature, a nonconductive resin film may be attached on the metal film.

The nonconductive resin film of the contact probe for testing a liquid crystal display according to the present invention may include a polyimide resin film, the contact pins may be constructed of a metal of Ni or a Ni alloy plated with Au and the metal film may be constructed of a film made of Ni, a Ni alloy, Cu or a Cu alloy.

In order to achieve the second object, according to another aspect of the present invention, in order to align both of a front end bent upwardly and a front end bent downwardly on contact pins with a normal front end, in respect of a structure of a contact probe, a highly elastic film including an organic or an inorganic material is attached on a first layer of a nonconductive resin film such that the highly elastic film is projected more shortly than the contact pin to a side where the front end portions of the contact pins are projected from the first layer of the nonconductive resin film.

### BRIEF DESCRIPTION OF THE DRAWINGS

A more complete appreciation of the present invention and many of the attendant advantages thereof will be readily obtained as the same becomes better understood by reference to the following detailed description when considered in connection with the accompanying drawings, wherein:

FIG. 1 is a perspective outline view of a portion of a first embodiment of a contact probe for testing a liquid crystal display according to the present invention;

FIG. 2 is a sectional view taken from a line C-C of FIG. 1;

FIGS. 3(a) through 3(h) are explanatory outline views showing a fabrication method according to the first embodiment;

FIG. 4 is a sectional view showing a modified example of the first embodiment;

FIG. 5 is a perspective outline view of a portion of a second embodiment of a contact probe for testing a liquid crystal display according to the present invention;

FIG. 6 is a sectional view taken from a line C-C of FIG. 5;

FIG. 7 is an explanatory outline view showing a method of using the second embodiment;

FIGS. 8(a) through 8(i) are explanatory outline views showing a fabrication method of the second embodiment;

FIG. 9 is a perspective outline view of a portion of a modified example in the second embodiment;

FIG. 10 is a sectional view taken from a line E-E of FIG. 9;

FIG. 11 is an explanatory outline view showing a method of using the modified example;

FIGS. 12(a) through 12(h) are explanatory outline views showing a fabrication method of the modified example;

FIG. 13 is an explanatory outline view of a section of another modified example of the second embodiment;

FIG. 14 is an explanatory outline view of a section of still another modified example of the second embodiment;

FIG. 15 is an explanatory outline view showing a method of using the modified example;

FIG. 16 is an explanatory outline view of a section of still another modified example of the second embodiment;

FIG. 17 is a sectional view showing an example of an embodiment;

FIG. 18 is a sectional view showing by exaggeration a drawback in an embodiment;

FIG. 19 is a side view showing essential portions of a third embodiment of a liquid crystal display testing device according to the present invention;

FIG. 20 is a side view showing a state of using the device;

FIGS. 21(a) through 21(h) are sectional views of essential portions showing a fabrication method of a contact probe constituting the device in an order of steps;

FIG. 22 is a side sectional view of the contact probe;

FIG. 23 is a disassembled perspective view showing essential portions of the liquid crystal display testing device;

FIG. 24 is a sectional view thereof of the liquid crystal display testing device;

FIG. 25 is a perspective view thereof of the liquid crystal display testing device;

FIG. 26 is a front view for explaining a metal film of the contact probe;

FIG. 27 is a perspective outline view of a background contact probe;

FIG. 28 is a sectional view taken from a line A-A of FIG. 27;

FIG. 29 is a disassembled perspective view of a jig for attaching the background contact probe;

FIG. 30 is a perspective view of a state in which the background contact probe is attached to a jig;

FIG. 31 is a perspective outline view showing a state in which the background contact probe is attached to the jig, which is attached to a frame;

FIG. 32 is a sectional view taken from a line B-B of FIG. 31 showing a state in which the background contact probe is attached to the jig, which is attached to the frame;

FIG. 33 is a front view viewing in D direction the background contact probe in FIG. 27;

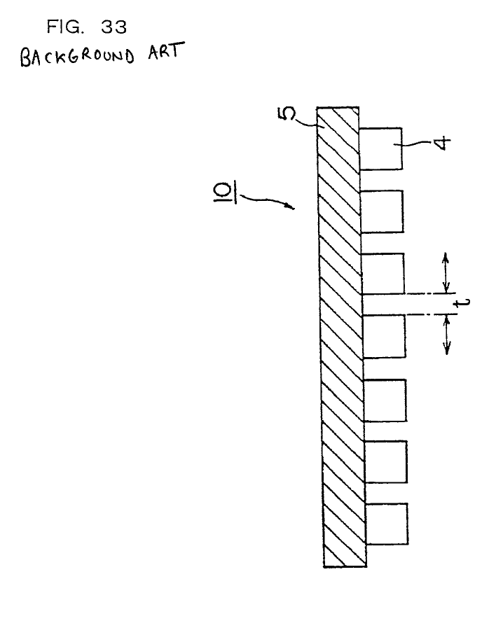

FIG. 34 is a sectional view of the background contact probe for testing a liquid crystal display; and

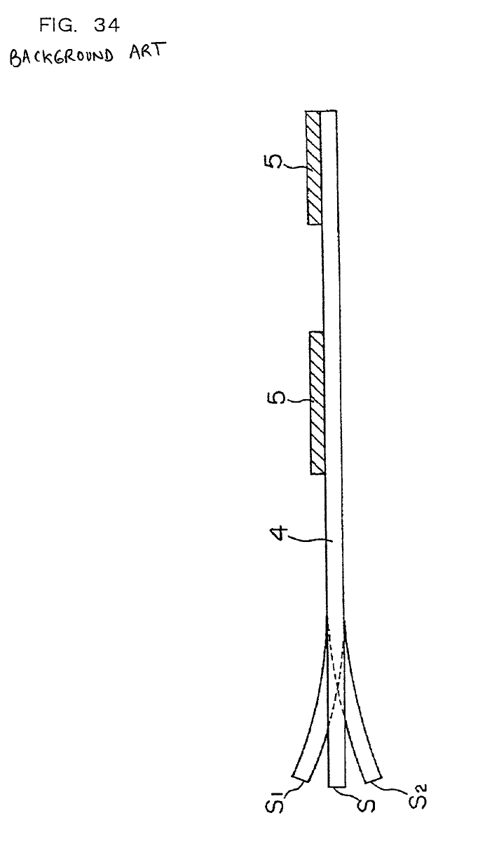

FIG. 35 is a sectional view in a case where the conventional contact probe for testing a liquid crystal display is used.

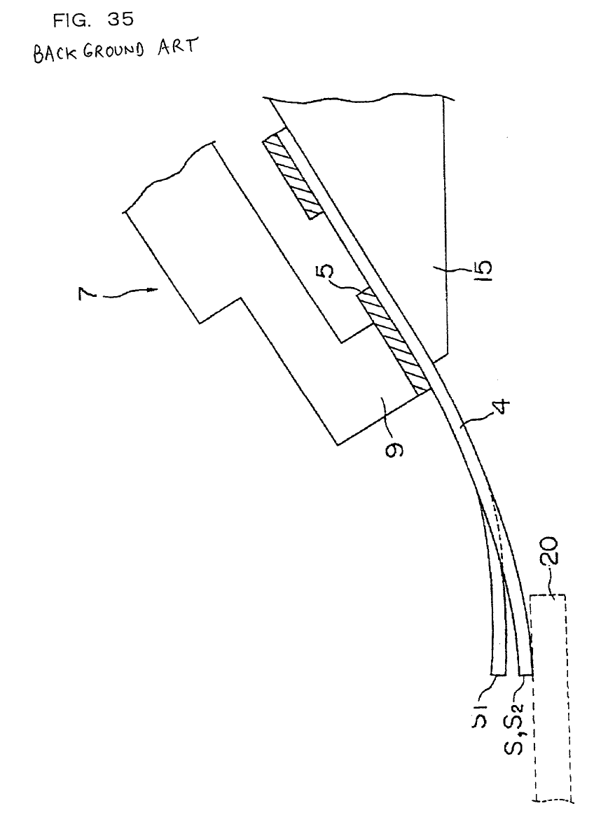

### DETAILED DESCRIPTION OF THE PREFERRED EMBODIMENTS

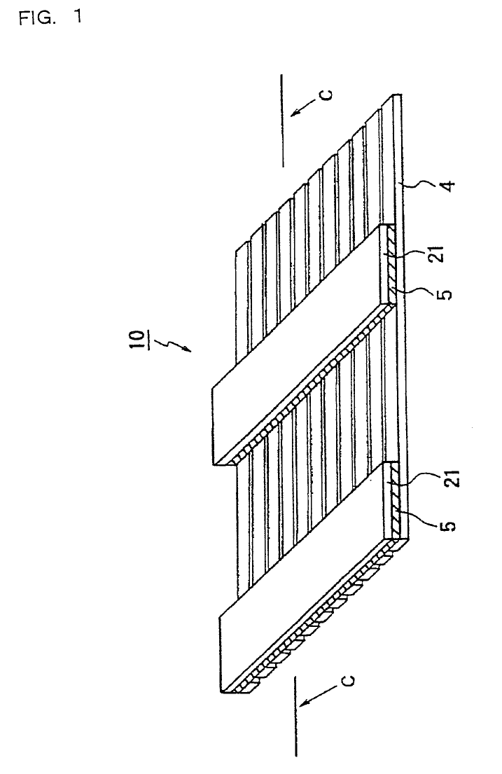

An explanation will be given of a first embodiment in respect of a contact probe of the present invention with reference to FIG. 1 through FIG. 4.

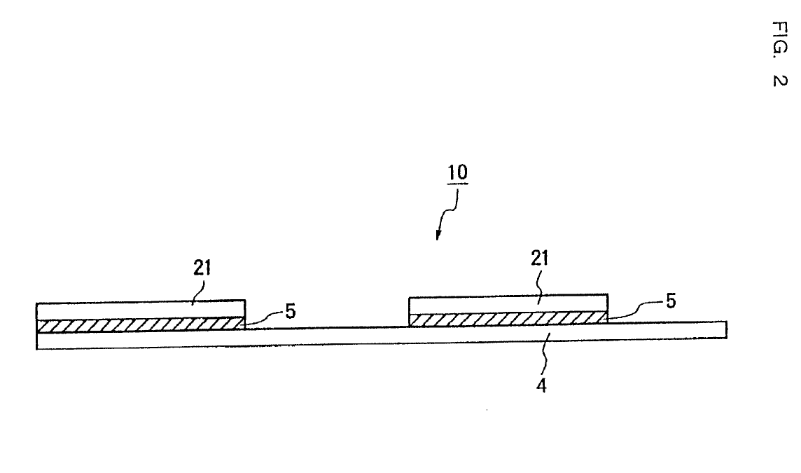

According to a first aspect of the present invention, as shown in a perspective view of FIG. 1 and a sectional view of the line C-C in FIG. 1 in FIG. 2, a metal film 21 is attached on a nonconductive resin film 5 of a contact probe 10 for testing a liquid crystal display including the contact pins 4 and the nonconductive resin film 5.

According to the contact probe 10, even if humidity is changed, the changes in the intervals t between the contact pins 4 are smaller than those in a background contact probe 10 by which the front end portions of the contact pins of the contact probe can accurately be brought into contact with the liquid crystal display.

According to the present invention as shown in FIG. 1 and FIG. 2, FIG. 2 being the sectional view taken from a line C-C of FIG. 1, the present invention includes a feature that in respect of a contact probe 10 for testing a liquid crystal display by attaching contact pins 4 arranged in parallel on one face of a nonconductive resin film 5 such that the contact pins 4 are orthogonal to the nonconductive resin film 5 and front end portions of the contact pins 4 are projected from the nonconductive resin film 5, a metal film 21 is further attached on the nonconductive resin film 5.

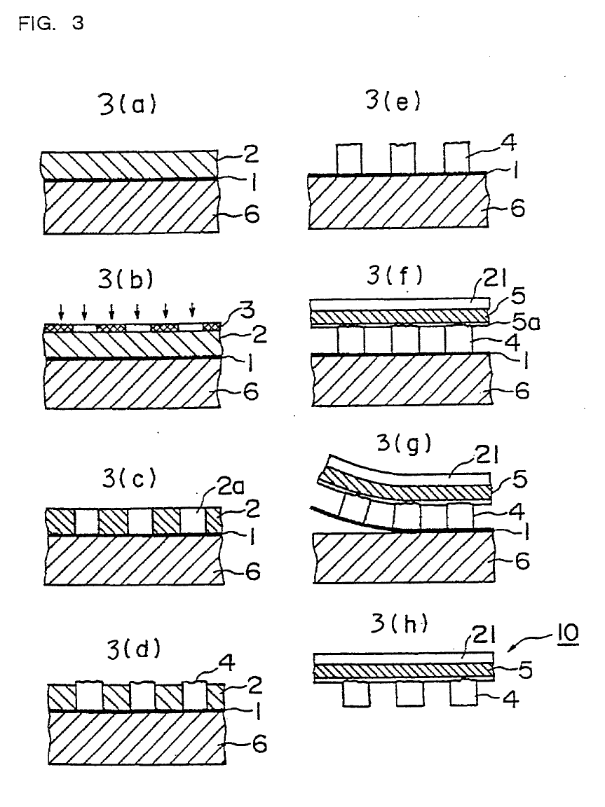

FIGS. 3(a) through 3(h) show a fabrication method of a contact probe 10 of the present invention. Firstly, a base metal layer 1 made of, e.g., Cu is formed on a support metal plate 6 made of, e.g., stainless steel, and a photoresist layer 2 is formed on the base metal layer 1 (FIG. 3(a)). A mask 3 of a predetermined pattern is applied on the photoresist layer 2 and an exposure operation is conducted (FIG. 3(b)). The photoresist layer 2 is developed, portions to constitute the contact pins 4 are removed and openings 2a are formed on the remaining photoresist layer 2 (FIG. 3(c)). A Ni layer to constitute the contact pins 4 are formed by plating at the openings 2a (FIG. 3(d)) and the photoresist layer 2 is removed (FIG. 3(e)). Incidentally, although the photoresist layer 2 is formed by a positive photoresist according to this embodiment, the desired openings 2(a) may be formed by adopting a negative photoresist. Further, according to this embodiment, the photoresist layer 2 corresponds at a “mask”. However, the “mask” is not limited to one in which the openings 2a are formed after the mask has been subjected to the exposure and development steps using the photomask 3, as in the photoresist layer 2 of this embodiment. For example, the “mask” may be a film or the like in which holes have been previously perforated at portions to be plated (that is, previously formed in a state designated by numeral 2 of FIG. 3(c)). When such a film is used as the “mask”, the pattern forming step in the embodiment is not necessary.

Next, a composite film including the nonconductive resin film 5 and the metal film 21 is adhered onto the Ni layer via an adhesive agent 5a (FIG. 3(f)). A portion including the nonconductive resin film 5, the contact pins 4 and the base metal layer 1 is separated from the support metal plate 6 (FIG. 3(g)) and the base metal layer 1 is removed by which the contact probe 10 in which the nonconductive resin film 5 and the metal film 21 are adhered to the contact pins 4 is fabricated (FIG. 3(h)).

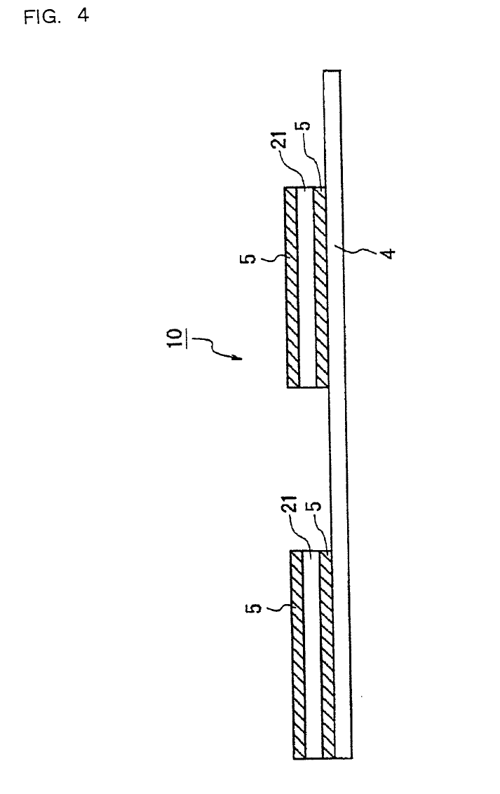

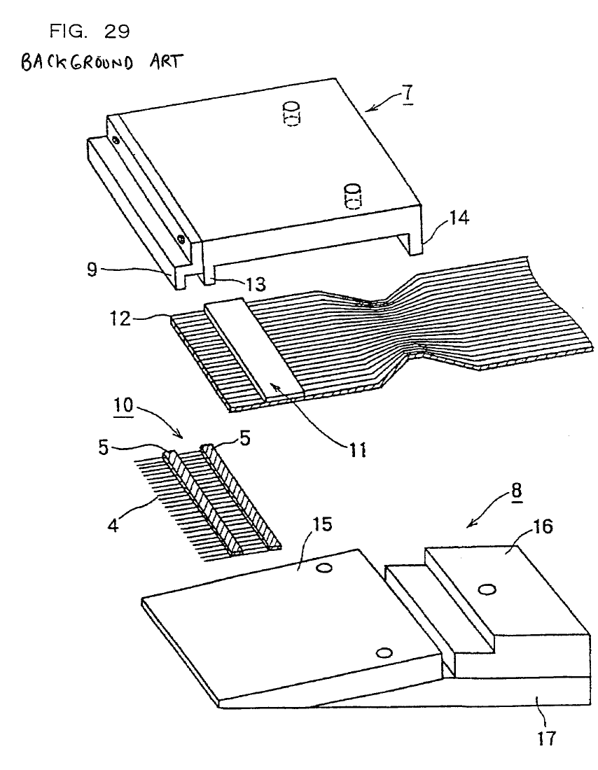

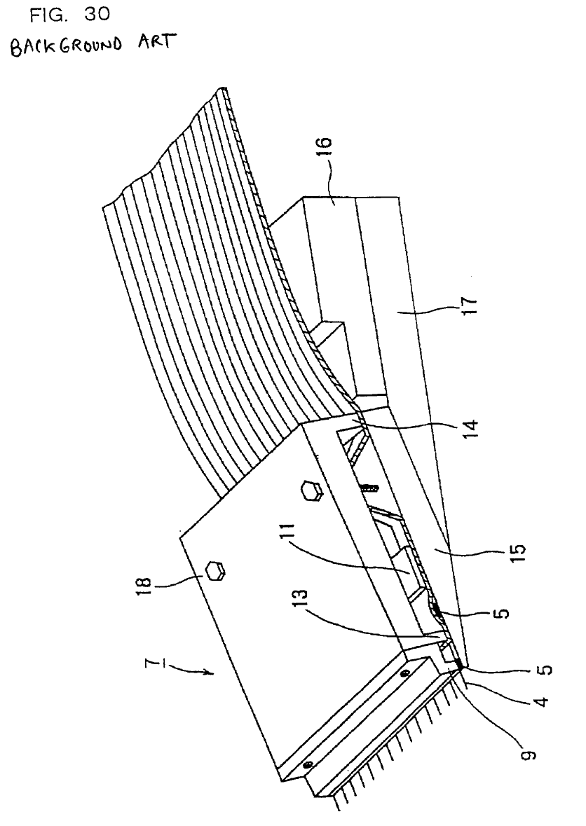

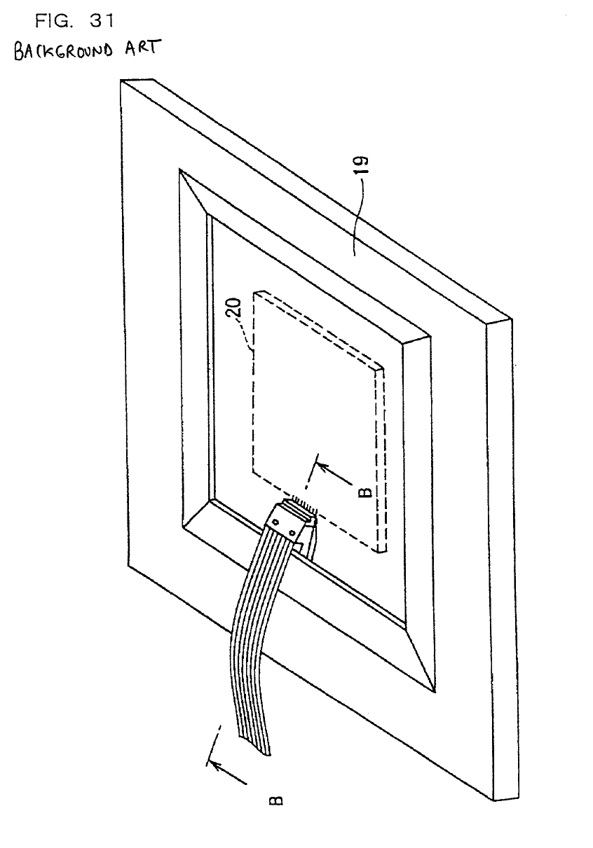

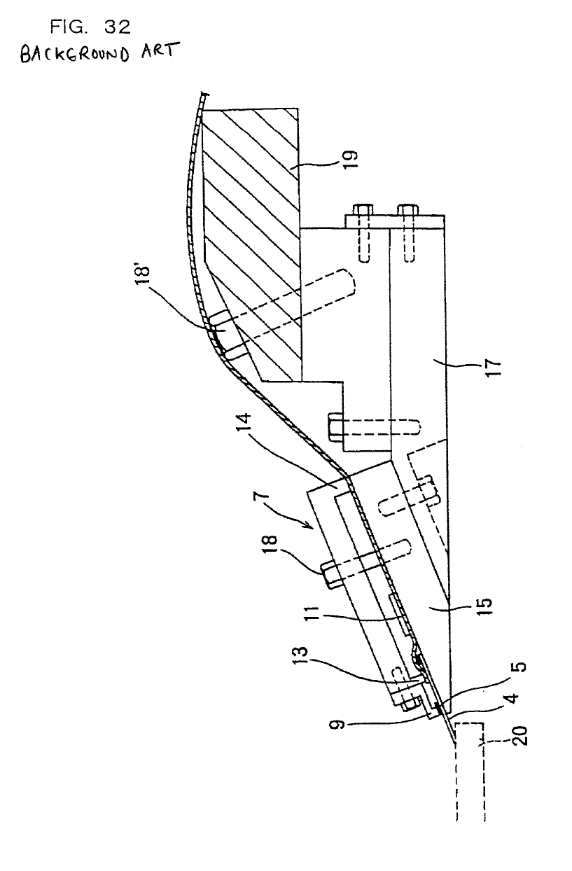

As shown by a sectional view in FIG. 4, in respect of the contact probe 10 of the present invention, a composite film in which the nonconductive resin film 5, the metal film 21 and the nonconductive resin film 5 are adhered in this order may be formed on the contact pins 4. Further, the method of using the contact probe of the present invention is quite the same as the method of using the background contact probe described with reference to FIG. 29 through FIG. 32.

A contact probe of the present invention having a distance between pins at both ends of 9.900 mm with a structure in which a nonconductive resin film 5 made of polyimide resin having a thickness of 50 μm and a pure copper film 21 were attached on contact pins 4 made of Ni having a pitch of 100 μm and a number of pins 4 of 100 at normal temperature was fabricated by the method shown in FIGS. 3(a) through 3(h).

Meanwhile, a background contact probe having a distance between pins at both ends of 9.900 mm with a structure in which a nonconductive resin film made of polyimide resin having a thickness of 50 μm was attached on contact pins made of Ni having a width of 100 μm and a number of pins of 100 at normal temperature was fabricated for comparison.

As a result of holding the contact probe of the present invention and the background contact probe in an atmosphere of temperature of 25° C. and humidity of 70% for 3 hours, and thereafter measuring a distance between the contact pins at both ends of the contact probe of the present invention and the background comparison contact probe, the distance between the contact pins at the both ends of the contact probe of the present invention was 9.8976 mm, whereas the distance between the contact pins at the both ends of the background comparison contact probe was 9.8712 mm. This indicates that changes in the distance between the contact pins at the both ends of the structure of the present invention in which the pure copper film 21 was attached were small.

As described above, according to the contact probe of the present invention, the changes in the distances between contact pins 4 at the both ends of the contact probe are small even under an environment of high temperature and high humidity. Accordingly, front end portions of the contact pins 4 can be brought into contact with predetermined positions of a liquid crystal display accurately under any environment and inspection failure of a liquid crystal display is eliminated. The result significantly contributes to the development of the semiconductor industry.

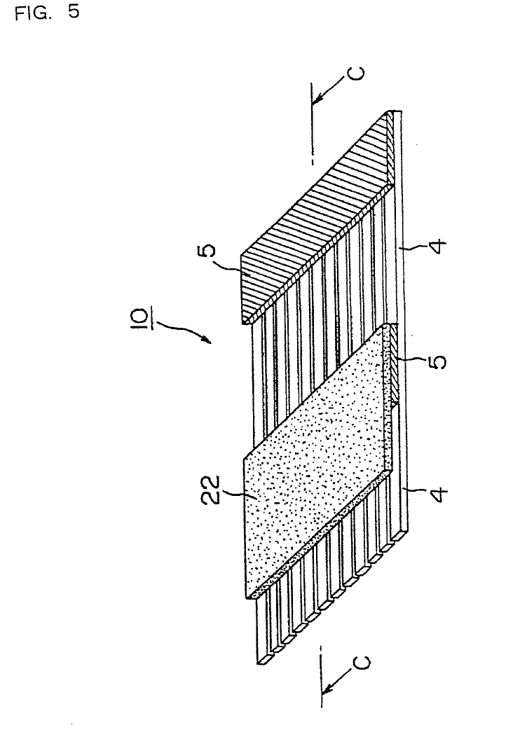

Next, an explanation will be given of a second embodiment of the present invention with reference to FIG. 5 through FIG. 16. Description of leads on the side of a TABIC and the like are omitted in these drawings.

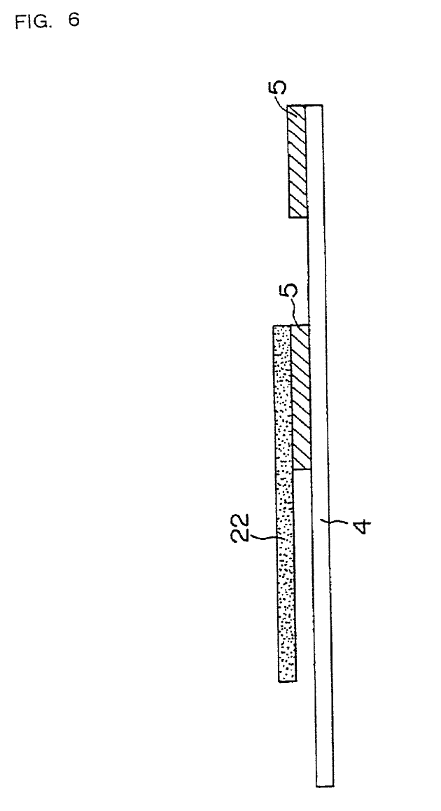

As shown in FIG. 5 and FIG. 6, FIG. 6 being a sectional view taken from a line C-C of FIG. 5, this embodiment includes a feature that in a contact probe 10 for testing a liquid crystal display in which the contact pins 4 arranged in parallel are attached on one face of a first layer of a nonconductive resin film 5 such that the contact pins 4 are orthogonal to the first layer of the nonconductive resin film 5 and front end portions of the contact pins 4 are projected from the first layer of the nonconductive resin film 5, a highly elastic film 22 including an organic or an inorganic material is attached on the first layer of the nonconductive resin film 5. The highly elastic film 22 is projected more shortly than the contact pins 4 to the side where the front end portions of the contact pins 4 are projected from the first layer of the nonconductive resin film 5.

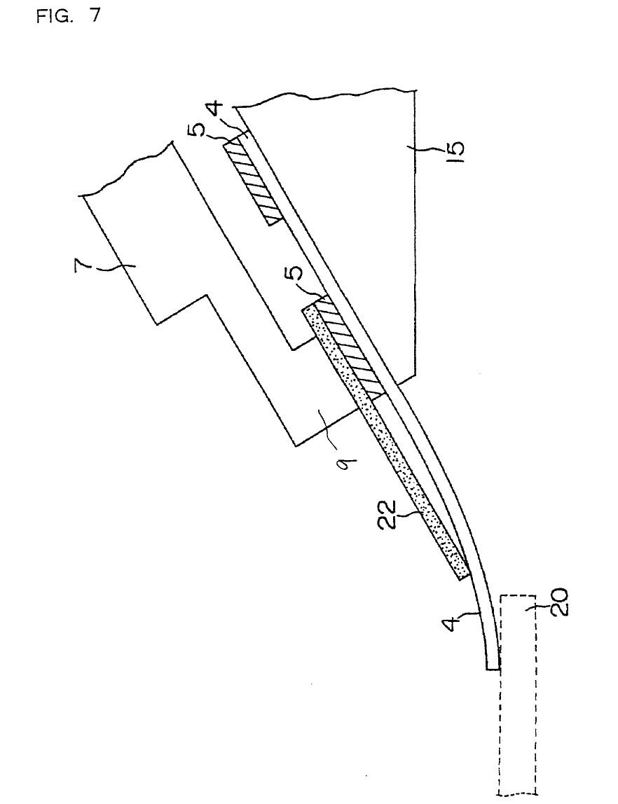

As shown in a sectional view of FIG. 7, when the contact pins 4 of the contact probe 10 are pinched by the first projection 9 of the top clamp 7 and the contact pins 4 are pressed onto the liquid crystal display 20, the highly elastic film 22 installed to the contact probe 10 presses the front end portions of the contact pins 4 from an upper side thereof, and therefore the front end S1 bent upwardly is brought into contact with the terminal of the liquid crystal display 20, with the result that a uniform contact pressure is obtained for the respective pins and measurement failure caused by contact failure of the contact pin 4 in respect of the liquid crystal display 20 is eliminated. Furthermore, by changing an amount of projecting the contact pin 4 from the highly elastic film 22, a timing for pressing the contact pin 4 from the upper side can be changed, whereby a desired contact pressure can be obtained by a desired amount of pressing.

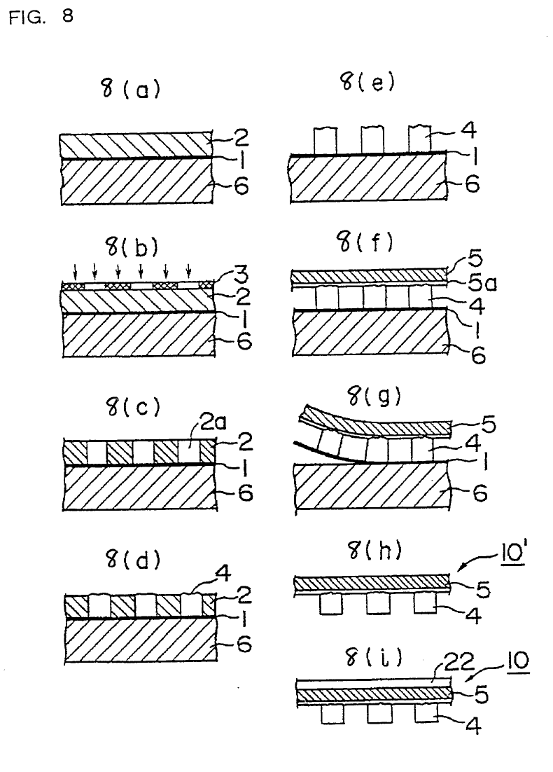

An explanation will be given of a fabrication method of the contact probe 10 according to this embodiment with reference to FIGS. 8(a) through 8(i). As shown in FIGS. 8(a) through 8(i), the steps in FIGS. 8(a) through 8(h) are the same as the steps shown by FIGS. 3(a) through 3(h) of the first embodiment. Further, the highly elastic film 22 is adhered onto the first layer of the nonconductive resin film 5 of the contact probe 10′ obtained, thereby by which the contact probe 10 of the present invention is obtained (FIG. 8(i)).

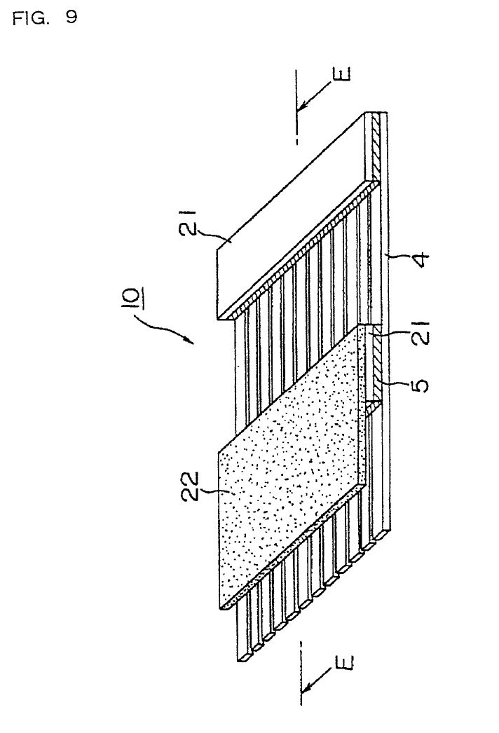

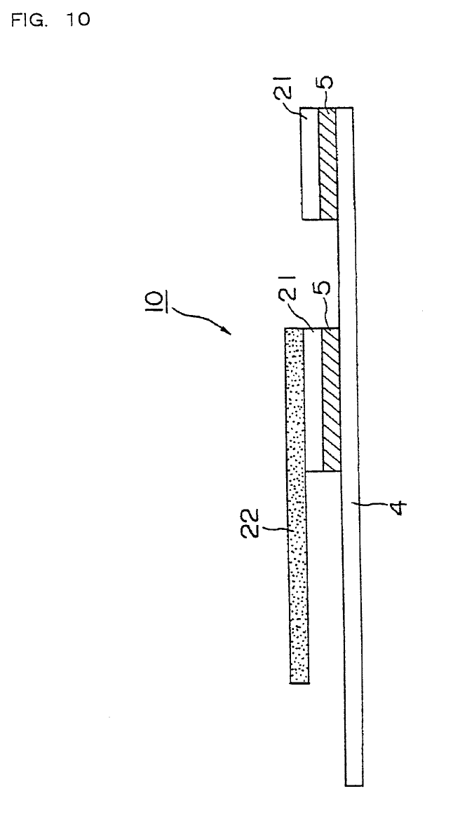

As shown in FIG. 9 and FIG. 10, FIG. 10 being a sectional view taken from a line E-E of FIG. 9, a modified example of the second embodiment includes a feature that in a contact probe 10 for testing a liquid crystal display in which the contact pins 4 arranged in parallel are attached on one face of the first layer of the nonconductive resin film 5 such that the contact pins 4 are orthogonal to the first layer of the nonconductive resin film 5 and the front end portions of the contact pins 4 are projected from the first layer of the nonconductive resin film 5, the metal film 21 is attached on the first layer of the nonconductive resin film 5. Further, the highly elastic film 22 including an organic or an inorganic material is attached on the metal film 21 such that the highly elastic film 22 is projected more shortly than the contact pins 4 to the side where the front end portions of the contact pins 4 are projected from the first layer of the nonconductive resin film 5.

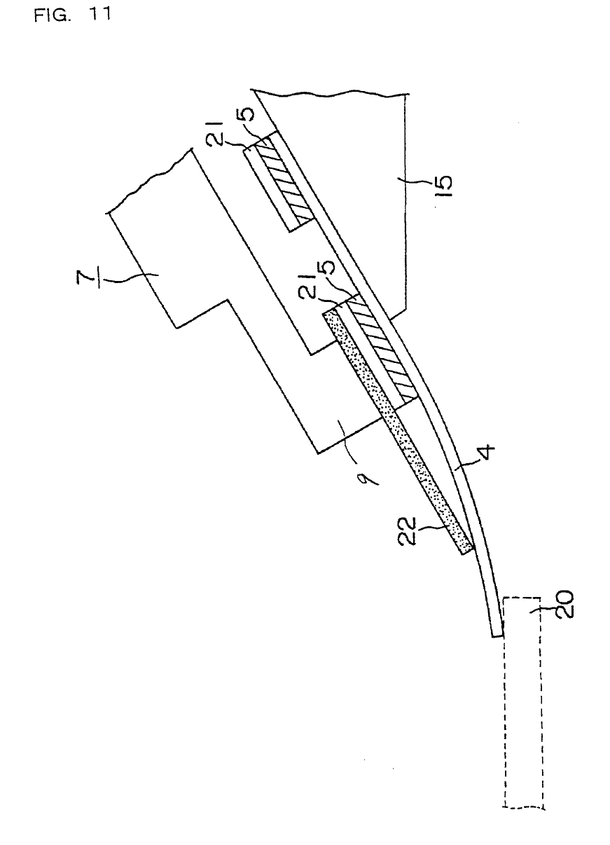

As shown in FIG. 11, when the contact pins 4 of the contact probe 10 having the structure shown in FIG. 9 and FIG. 10 are pinched by the first projection 9 of the top clamp 7 and the inclined plate 15 and the contact pins 4 are pressed to the liquid crystal display 20, the highly elastic film 22 installed in the contact probe 10 presses the front end portions of the contact pins 4 from an upper side thereof, and therefore a front end S1 of a contact pin 4 which is bent upwardly is also brought into contact with a terminal of the liquid crystal display 20 with a contact pressure the same as those of the other contact pins. Further, changes in intervals t between the contact pins 4 are smaller than those of a background contact probe even if the humidity or the like is changed, and thereby the front end portions of the contact pins 4 of the contact probe 10 can be brought into contact with the liquid crystal display 20 more accurately.

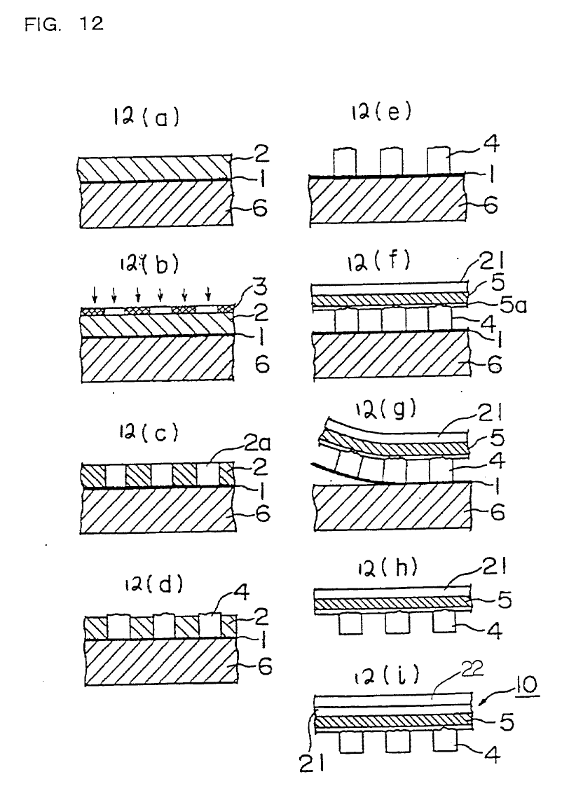

A contact probe 10 in respect of a modified example of the second embodiment is fabricated by the steps shown in FIGS. 12(a) through 12(i). That is, as shown in FIGS. 12(a) through 12(e), the steps are the same as those of the second embodiment shown in FIGS. 8(a) through 8(e).

Then, in step 12(f), a composite film including a first layer of the nonconductive resin film 5 and the metal film 21 is adhered via an adhesive agent 5a onto an Ni layer except at front end portions of the contact pins 4. Further, a portion including the first layer of the nonconductive resin film 5, the contact pins 4 and the base metal layer 1 is separated from the support metal plate 6 (FIG. 12(g)), and successively the base metal layer 1 is removed by which a contact probe in which the first layer of the nonconductive resin film 5 and the metal film 21 are adhered to the contact pins 4 is fabricated (FIG. 12(h)). The highly elastic film 22 is adhered onto the metal film 21 of the obtained contact probe by which the contact probe 10 according to the present invention is provided (FIG. 12(i)).

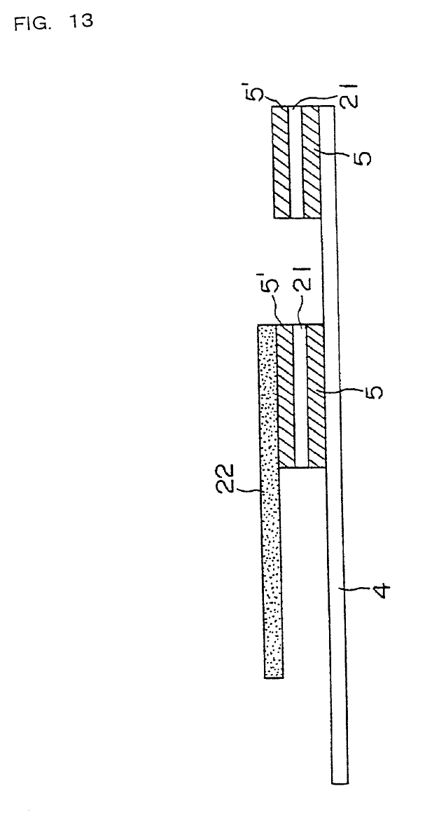

As shown in a sectional view of FIG. 13, a contact probe 10 of the present invention may be fabricated as follows. The metal film 21 is attached on a first layer of the nonconductive resin film 5, a second layer of the nonconductive resin film 5′ is attached further on the metal film 21 and the highly elastic film 22 including an organic or an inorganic material is attached on the second layer of the nonconductive resin film 51 such that the highly elastic film 22 is projected more shortly than the contact pins 4 to the side where the front end portions of the contact pins 4 are projected from the first layer of the nonconductive resin film 5.

Accordingly, as shown in the sectional view of FIG. 13, the present invention includes a feature in a contact probe for testing a liquid crystal display in which the contact pins 4 arranged in parallel are attached on one face of the first layer of the nonconductive resin film 5 such that the contact pins 4 are orthogonal to the first layer of the nonconductive resin film 5. Further, front end portions of the contact pins 4 are projected from the first layer of the nonconductive resin film 5, the metal film 21 is attached on the first layer of the nonconductive resin film 5, the second layer of the nonconductive resin film 5′ is further attached on the metal film 21 and the highly elastic film 22 including an organic or an inorganic material is attached on the second layer of the nonconductive resin film 5′ such that the highly elastic film 22 is projected more shortly than the contact pins 4 to the side where the front end portions of the contact pins 4 are projected from the first layer of the nonconductive resin film 5.

Although the contact probes in respect of the second embodiment and the modified examples thereof achieve an excellent effect as described above, as shown in FIG. 7 and FIG. 11, the highly elastic film 22 is brought into press contact with the contact pins 4. However, even with respect to such a contact probe of the present invention, if it is repeatedly used for a number of times, press contact between the highly elastic film 22 and the contact pins 4 is repeated and when distortion is accumulated by repeating the friction, the contact pins 4 may be bent in left and right directions, whereby points of contact may be shifted.

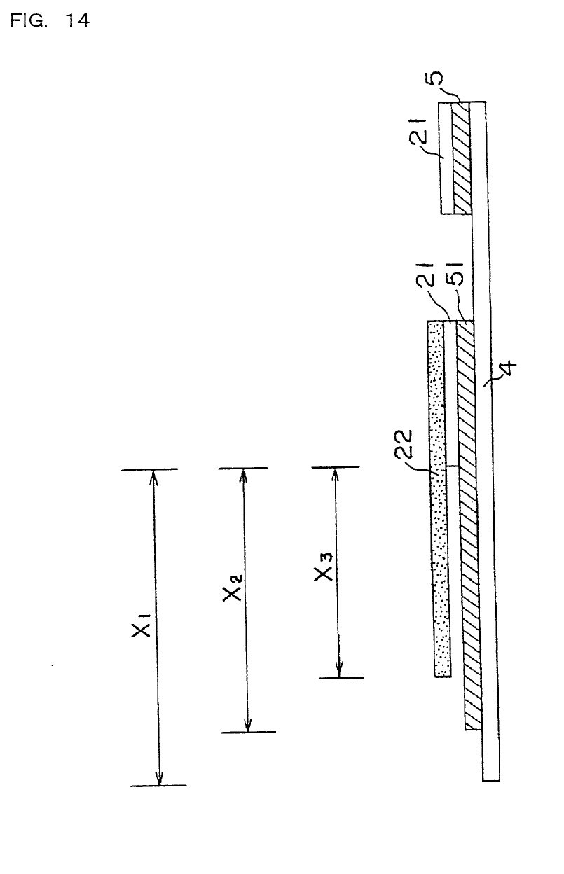

In order to improve such a shortcoming, as shown in FIG. 14, a contact probe of the present invention may have the following structure. A first layer 51 of a nonconductive resin film adhered to the contact pins 4 is constituted by a film having a width wider than that of a conventional film. After adhering the first layer of a nonconductive resin film 51 having a wide width, the metal film 21 is attached on the first layer of the nonconductive resin film 51 having the wide width and the highly elastic film 22 is attached on the metal film 21. In respect of a relationship among a projected length X1 of the contact pins 4, a projected length X2 of the first layer of the nonconductive resin film 51 having the wide width and a projected length X3 of the highly elastic film 22 in the contact probe of the present invention, a relationship of X1>X2>X3 is established.

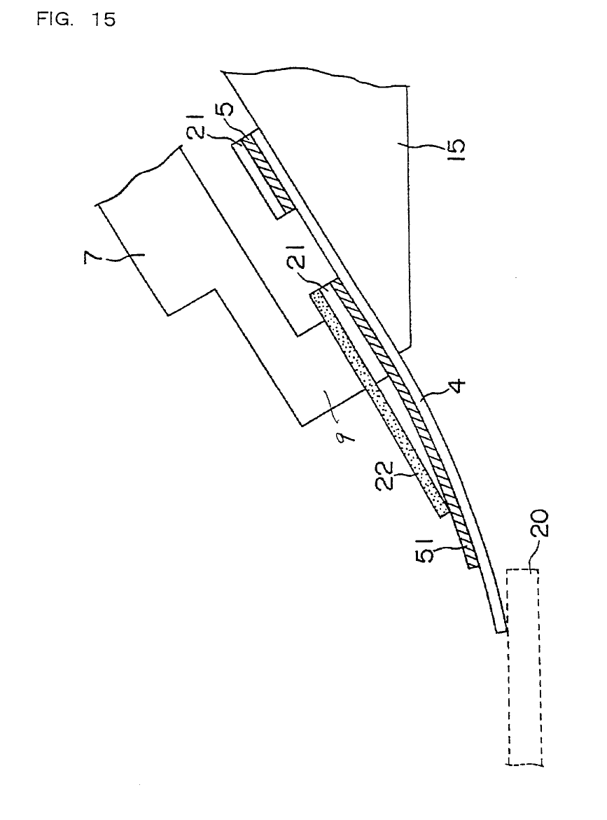

As shown in FIG. 15, when the contact pins 4 of the contact probe 10 are pinched by the first projection 9 of the top clamp 7 and the contact pins 4 are pressed to the liquid crystal display 20, the highly elastic film 22 installed to the contact probe 10 is brought into contact with the soft first layer of the nonconductive resin film 51 having the wide width and is not brought into direct contact with the contact pins 4, with the result that bending in the left and right directions of the contact pins 4 is avoided.

Accordingly, as shown in FIG. 14, the present invention includes a feature that in a contact probe for testing a liquid crystal display in which the contact pins 4 arranged in parallel are attached on one face of the first layer of the nonconductive resin film 51 having the wide width such that the contact pins 4 are orthogonal to the first layer of the nonconductive resin film 51 having the wide width, and further the front end portions of the contact pins are projected from the first layer of the nonconductive resin film 51 having the wide width, the metal film 21 is attached on the first layer of the nonconductive resin film 51 having the wide width. And further, the highly elastic film 22 including an organic or an inorganic material is attached on the metal film 21 such that the highly elastic film 22 is projected more shortly than the first layer of the nonconductive resin film 51 having the wide width to the side where the front end portions of the contact pins 4 are projected from the first layer of the nonconductive resin film 51 having the wide width.

Incidentally, the first layer of the nonconductive resin film 51 and the metal film 21 of the contact probe for testing a liquid crystal display according to the present invention may be formed as follows. A composite film including a nonconductive resin film and a metal film is previously prepared, a composite film including the first layer of the nonconductive resin film 51 having the wide width and the metal film 21 as shown in FIG. 14 is fabricated by partially etching the metal film of the former composite film and the composite film including the first layer of the nonconductive resin film 51 having the wide width and the metal film 21 is attached on the contact pins 4 which are arranged in parallel, thereby constituting the contact probe. Further, although the constitution in which the highly elastic film 22 is attached on the metal film 21 on the first layer of the nonconductive resin film 51 having the wide width is shown in FIG. 14, the constitution of the first layer of the nonconductive resin film 51 and the metal film 21 is effectively used also in the case in which the highly elastic film 22 is not used.

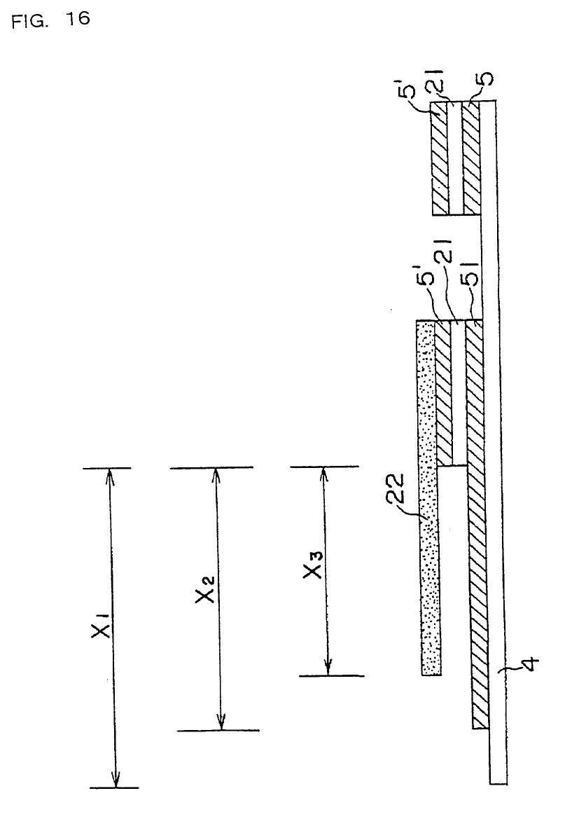

Furthermore, a contact probe of the present invention may be fabricated by attaching a second layer of a nonconductive resin film 5′ on the metal film 21 and attaching the highly elastic film 22 on the second layer of the nonconductive resin film 5′ as shown in FIG. 16. In respect of a relationship among the projected length X1 of the contact pins 4, the projected length X2 of the first layer of the nonconductive resin film 51 having the wide width and the projected length X3 of the highly elastic film 22, the relationship of X1>X2>X3 is established.

Accordingly, as shown in FIG. 16, the present invention includes a feature that in a contact probe for testing a liquid crystal display in which the contact pins 4 arranged in parallel are attached on one face of the first layer of the nonconductive resin film 51 having the wide width such that the contact pins 4 are orthogonal to the first layer of the nonconductive resin film 51 having the wide width and front end portions of the contact pins are projected from the first layer of the nonconductive resin film 51 having the wide width, the metal film 21 is attached on the first layer of the nonconductive resin film 51 having the wide width. The second layer of the nonconductive resin film 5′ is further attached on the metal film 21, and the highly elastic film 22 including an organic or an inorganic material is attached on the second layer of the nonconductive resin film 5′ such that the highly elastic film 22 is projected more shortly than the first layer of the nonconductive resin film 51 having the wide width to the side where the front end portions of the contact pins 4 are projected from the first layer of the nonconductive resin film 51 having the wide width.

Incidentally, the first layer of the nonconductive resin film 51 having the wide width and the metal film 21 of the contact probe for testing a liquid crystal display according to the present invention may be formed as follows. A composite film including a nonconductive resin film and a metal film is previously prepared, a composite film including the first layer of the nonconductive resin film 51 having the wide width and the metal film 21 is fabricated by partially etching the metal film of the former composite film as shown in FIG. 16, and the composite film including the first layer of the nonconductive resin film 51 having the wide width and the metal film 21 is attached on the contact pins 4 arranged in parallel, thereby forming the contact probe.

It is preferable that the metal film 21 used in the contact probe for testing a liquid crystal display is constructed of a metal film of Ni, a Ni alloy, Cu or a Cu alloy. Also, it is preferable that the highly elastic film 22 including an organic material is constructed of a polyethylene terephthalate film and the highly elastic film 22 including an inorganic material is constructed of a film of ceramics, particularly, alumina.

Further, it is preferable that both of the first layer of the nonconductive resin film 51 and the second layer of the nonconductive resin film 5′ of the contact probe for testing a liquid crystal display according to the present invention are formed by polyimide resin films, the contact pins 4 are constructed of a metal of Ni or a Ni alloy or a metal thereof plated with Au and the metal film 21 is constructed of a metal film made of Ni, a Ni alloy, Cu or a Cu alloy.

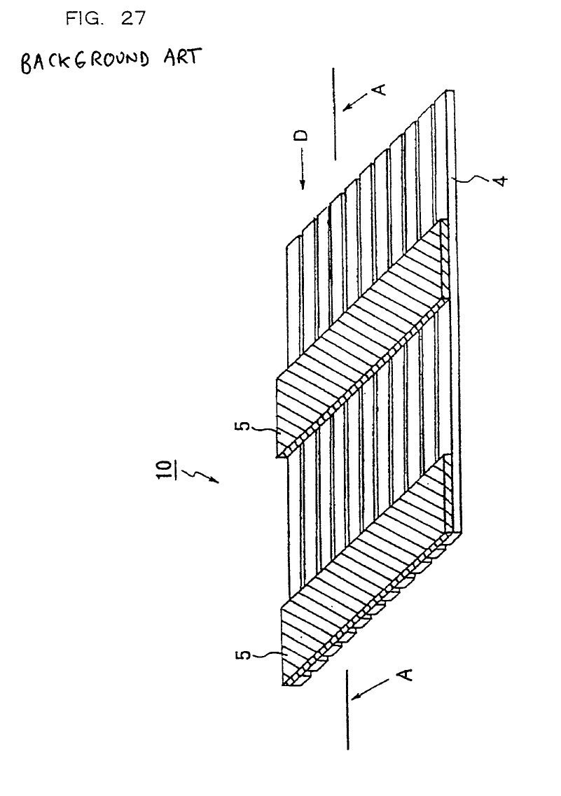

A method of using the contact probes according to the second embodiment and the modified examples thereof is quite the same as the method of using the background contact probe which has been described in reference to FIG. 27 through FIG. 32.

### EXAMPLE 1

A first layer of a nonconductive resin film 5 made of polyimide resin having a thickness of 40 μm was attached on contact pins 4 made of Ni having a pitch of 100 μm and a number of pins of 180 by the method shown in FIGS. 8(a) through 8(i) and a highly elastic film 22 made of polyethylene terephthalate having a thickness of 250 μm was attached on the first layer of the nonconductive resin film 5 made of polyimide such that the highly elastic film 22 is projected more shortly than the contact pins 4 made of Ni by 0.5 mm, by which a first example contact probe for testing a liquid crystal display according to the present invention having a structure shown in FIG. 5 and FIG. 6 was fabricated.

### EXAMPLE 2

A first layer of a nonconductive resin film 5 made of polyimide resin having a thickness of 50 μm was attached on contact pins 4 made of Ni having a pitch of 80 μm and a number of pins of 250 by the method shown in FIGS. 12(a) through 12(i). A metal film 21 made of beryllium copper having a thickness of 50 μm was attached on the first layer of the nonconductive resin film 5 made of polyimide and a highly elastic film 22 made of polyethylene terephthalate having a thickness of 300 μm was attached on the metal film 21 made of beryllium copper such that the highly elastic film 22 projected more shortly than the contact pins 4 made of Ni by 0.6 mm. A second example contact probe for testing a liquid crystal display according to the present invention having the structure shown in FIG. 9 and FIG. 10 was thereby fabricated.

### EXAMPLE 3

A first layer of a nonconductive resin film 5 made of polyimide having a thickness of 40 μm was attached on contact pins 4 made of Ni having a pitch of 75 μm and a number of pins of 200 by the method shown in FIGS. 12(a) through 12(i). A metal film 21 made of pure copper having a thickness of 35 μm was attached on the first layer of the nonconductive resin film 5 made of polyimide resin. A second layer of a nonconductive resin film 5′ made of polyimide resin having a thickness of 40 μm was attached on the metal film 21 made of pure copper and a highly elastic film 22 made of alumina having a thickness of 200 μm was attached on the second layer of the nonconductive resin film 5′ made of polyimide resin such that the highly elastic film 22 projected more shortly than the contact pins 4 made of Ni by 0.4 mm. A third example contact probe having the structure shown in FIG. 13 was thereby fabricated.

### EXAMPLE 4

A fourth example contact probe for testing a liquid crystal display according to the present invention having a structure in which contact pins 4 made of Ni having a pitch of 65 μm and a number of pins of 260 was fabricated. A first layer of a nonconductive resin film 5 made of polyimide resin having a wide width which has a thickness of 40 μm and a metal film 21 made of pure copper having a thickness of 18 μm and a highly elastic film 22 made of polyethylene terephthalate having a thickness of 250 μm were attached together such that X1 was equal to 1.5 mm, X2 was equal to 1.0 mm and X3 was equal to 0.9 mm, wherein X1 designates a projected length of the contact pins 4 made of Ni, X2 designates a projected length of the first layer of the nonconductive resin film 5 having the wide width and X3 designates a projected length of the highly elastic film 22 in FIG. 14.

### EXAMPLE 5

A fifth example contact probe for testing a liquid crystal display according to the present invention having a structure in which contact pins 4 made of Ni having a pitch of 100 μm and a number of pins of 320 was fabricated. A first layer of a nonconductive resin film 5 made of polyimide resin having a wide width which has a thickness of 40 μm, a metal film 21 made of pure copper having a thickness of 18 μm, a second layer of a nonconductive resin film 5′ made of polyimide resin having a thickness of 40 μm and a highly elastic film 22 made of alumina having a thickness of 200 μm, were attached together such that X1 was equal to 1.5 mm, X2 was equal to 1.2 mm and X3 was equal to 1.0 mm, wherein X1 designates a projected length of the contact pins 4 made of Ni, X2 designates a projected length of the first layer of the nonconductive resin film 5 having the wide width and X3 designates a projected length of the highly elastic film 22 in FIG. 16.

### BACKGROUND EXAMPLE 6

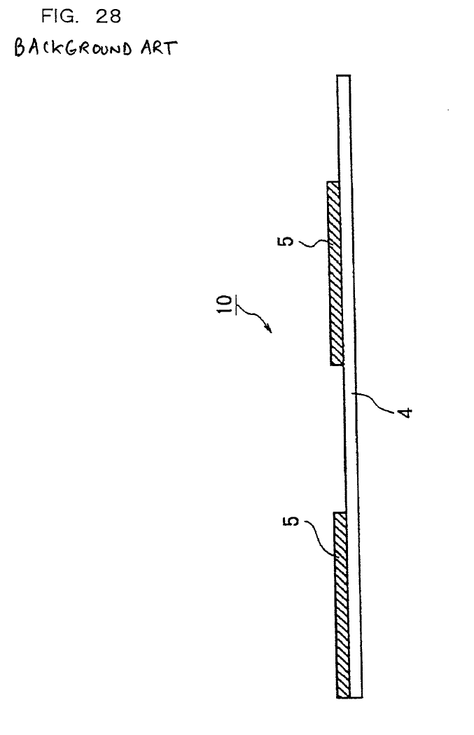

A background contact probe for testing a liquid crystal display shown in FIG. 27 and FIG. 28 having a structure in which a first layer of a nonconductive resin film 5 made of polyimide resin having a thickness of 50 μm was attached on contact pins 4 made of Ni having a pitch of 75 μm and a number of pins of 210 was fabricated.

When the first to fifth example contact probes for testing a liquid crystal display according to the present invention and the background contact probe for testing a liquid crystal display were pinched by a first projection of a top clamp and an inclined plate and the contact pins were pressed to the liquid crystal displays, although in respect of the first to fifth contact probes for testing a liquid crystal display according to the present invention, all of the contact pins were brought into contact with terminals of the liquid crystal displays since the highly elastic films pressed the front end portions of the contact pins from the upper side whereby failure of electric measurement could be eliminated. In respect of the background contact probe for testing a liquid crystal display, failure of electric measurement resulted.

Especially, with respect to the contact probes fourth and fifth example contact probes for testing a liquid crystal display according to the present invention, even if they were repeatedly used 100,000 times, no occurrence of bending of the contact pins in the left and right direction was caused and electric measurement was not hampered by a shift of contact points.

As described above, according to the contact probes for testing a liquid crystal display of the present invention, the front end portions of the contact pins can be accurately brought into contact with predetermined positions of a liquid crystal display and no failure of inspection of a liquid crystal display results, which significantly contributes to the development of the semiconductor industry.

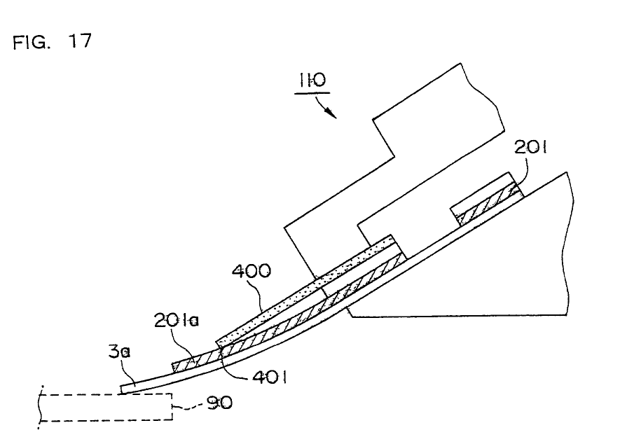

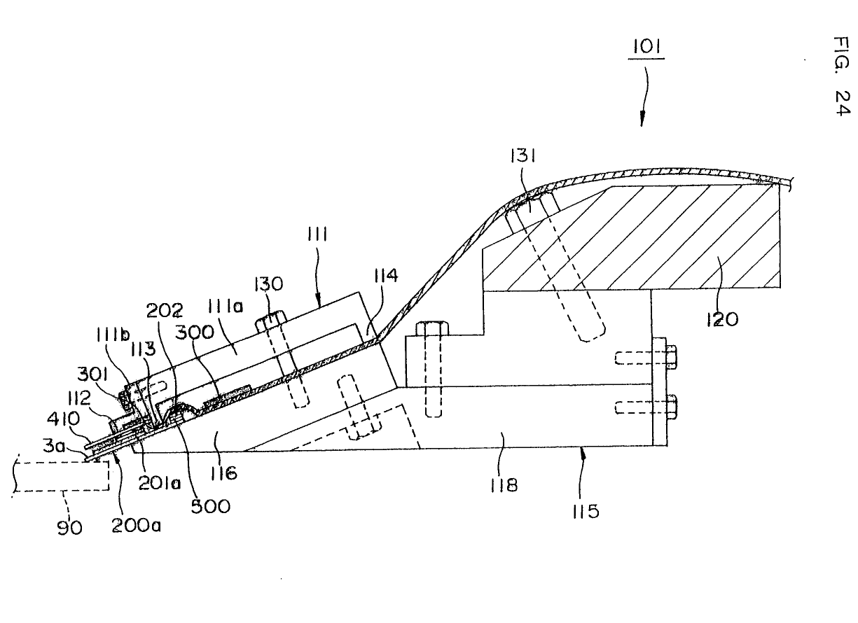

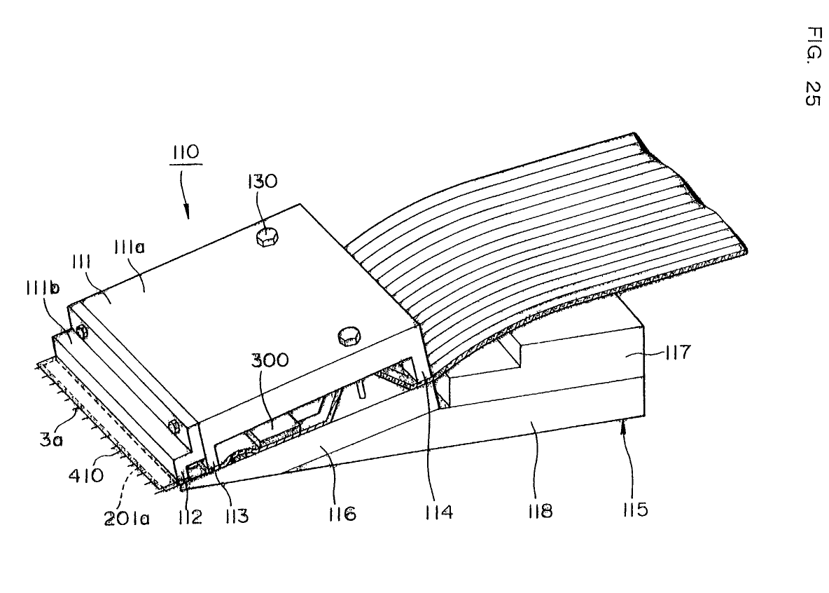

Next, an explanation will be given of a liquid crystal display testing device according to a third embodiment of the present invention with reference to FIG. 17 through FIG. 26. In these figures, illustration of a frame in a shape of a picture frame, leads on the side of a TABIC and the like, are omitted.

A pressing film (highly elastic film) is used in order to press the front end of the contact pin bent upwardly and bring it firmly into contact with a terminal of an LCD (Liquid Crystal Display).

However, in this case, when the highly elastic film is brought into press contact with the contact pin directly, friction between the highly elastic film and the contact pin is repeated by repeated use and distortion may thereby be accumulated, resulting in the contact pin possibly being bent in left and right directions and a point of contact being shifted.

Hence, as shown in FIG. 17, a resin film 201a having a larger amount of projection than that of a highly elastic film 400 is adopted in place of a background resin film. According to this structure, the resin film 201a prevents a contact pin 3a and the highly elastic film 400 from being brought into direct contact with each other and thereby functions as a buffer. Therefore, even if the contact pin 3a is overdriven repeatedly, the contact pin 3a is not warped, bent or the like by friction between the contact pin 3a and the highly elastic film 400, whereby stable contact can be maintained in respect of the terminal.

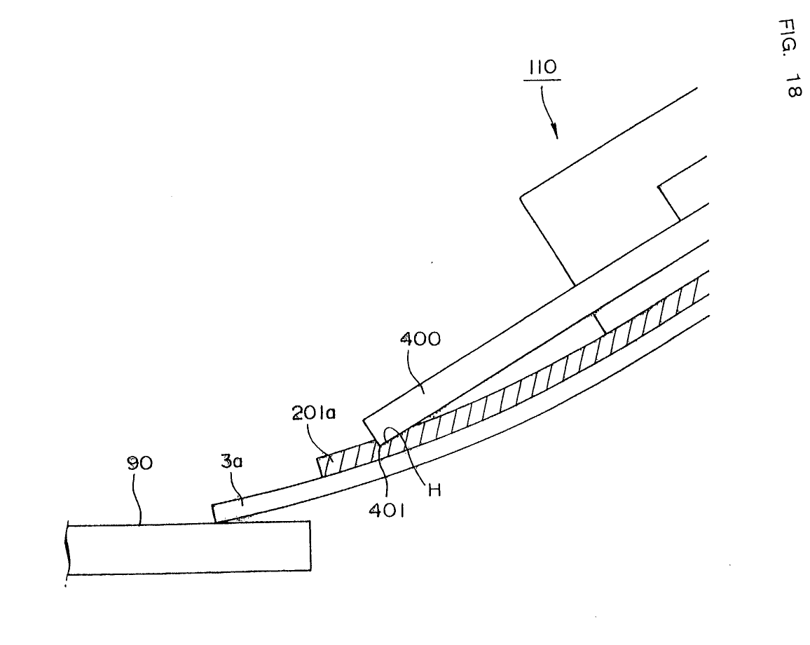

As shown in FIG. 17, when the contact pin 3a is overdriven, the resin film 201a is bent upwardly along with the contact pin 3a and at this moment the resin film 201a is relatively brought into sliding contact with a front end lower face (especially, a front end corner portion 401) of the highly elastic film 400. Meanwhile, a constant rigidity is required to the highly elastic film 400 since it has a function of pressing the contact pin 3a bent upwardly as described above and accordingly, for example, a ceramic material is used therefor. In the meantime, for example, polyimide resin is used for the resin film 201a. Accordingly, when a hardness of the resin film 201a and the highly elastic film 400 are compared with each other, the highly elastic film 400 is harder, and when an abrasive contact between the resin film 201a and the highly elastic film 400 (401) is repeated, the sliding contact face of the resin film 201a is worn (refer to notation H of FIG. 18).

When the sliding contact face of the resin film 201a is roughened by wear and a recess H is formed on its surface, the sliding movement performance of the resin film 201a and the highly elastic film 400 in overdriving the contact pin 3a is deteriorated, whereby the contact performance between the contact pin 3a and the terminal of the LCD 90 is deteriorated.

Moreover, when the recess H is formed on the sliding contact face of the resin film 201a, the pressing force exerted by the highly elastic film 400 via the resin film 201a is decreased by a magnitude in respect of the recess H, and a predetermined pressing amount may not operate on the contact pin 3a. As a result, the pressing amount of the contact pin 3a in respect of the terminal of the LCD 90 is deficient, thereby causing contact failure. Further, in this case, the contact is susceptible to influences of vibration from a peripheral instrument (for example, a vibration of a motor of a prober) and the contact pin 3a may be attached to or detached from the terminal.

Further, because of a similar reason, even if a contact state of the contact pins 3a in respect of the terminals is maintained, amounts of pressing the contact pin 3a in respect of the terminals respectively differ, and accordingly differences in the contact pressures in respect of the terminals arise, and as a result wear states (flatness at a pin tip) of the contact pins 3a by the repeated use differ, which may cause a contact failure.

Further, according to a liquid crystal display testing device, a plurality of contact probe pinching bodies 110 are installed, and therefore an amount of wear of the resin film 201a may differ depending on the respective contact probe pinching bodies 110, and in this case a dispersion is caused in the contact states of the respective contact pins 3a in respect of the terminals.

Furthermore, the resin film 201a gives off dust by wear, which further deteriorates the testing environment.

It is an object of a further embodiment of the present invention to provide a liquid crystal display testing device in which wear of a film caused by sliding contact with a pressing film is minimized and a pressing force (pressing amount) exerted from the pressing film to contact pins via the film is maintained constant.

An embodiment of the present invention adopts the following constitution in order to resolve the above-described problem. That is, an embodiment adopts the following technology relating to a liquid crystal display testing device in which a contact probe, in which a plurality of pattern wirings are formed on a film and respective front ends of the pattern wirings are arranged to project from the film, thereby constituting contact pins, is connected to a circuit having terminals that are connected to respective base ends of pattern wirings. The liquid crystal display testing device is provided with a pressing film which is arranged above the film and which presses the contact pins toward an object of measurement via the film when the contact pins are brought into contact with the object of measurement in a pressing state, and a holding member for holding the pressing film and the contact probe. The pressing film is arranged to project from the film such that a front end corner portion thereof is not brought into contact with the film when the pressing film presses the contact pins via the film and an amount of projection from the film in respect of the pressing film is set to be smaller than that of the contact pins such that the pressing film is not brought into contact with the contact pins.

According to the liquid crystal display testing device, the pressing film is arranged to project from the film such that when the pressing film presses the contact pins via the film, the front end corner portion thereof is not brought into contact with the film, and accordingly the pressing film is brought into sliding contact with the film only at a lower face thereof except at the front end corner portion. Therefore, the contact pressure of the pressing film in respect of the film is reduced by that amount and wear of the film is minimized. Therefore, the sliding movement performance between the pressing film and the film is not deteriorated in the overdriving operation and the contact performance between the contact pins and the object of measurement is not deteriorated. Also, dust generation by wear of the film is minimized.

Further, a recess portion caused by wear is not formed on the face of the film, and therefore, the pressing force from the pressing film is exerted on the contact pins via the film by only a predetermined amount of pressing. Therefore, the amount of pressing of the contact pins in respect of the object of measurement is not deficient, which prevents contact failure from resulting. Also, for a similar reason, contact pressures of the respective contact pins in respect of the object of measurement are made uniform, and as a result, a wear state (flatness of a pin tip) of the contact pins due to repeated use is also made uniform.

According to a liquid crystal display testing device of the present invention, the amount of projecting of the pressing film from the resin film is set to be smaller than those of the contact pins such that the pressing film is not brought into contact with the contact pins when the pressing film presses the contact pins via the film, and accordingly the pressing film does not directly press the contact pins and the film therebetween buffers the pressing force from the pressing film. Accordingly, even with repeated use, the contact pins are not warped, bent or the like by friction between the film and the pressing film.

Further, a modified example of the embodiment adopts a technology in which a treatment for lowering the friction coefficient is conducted in respect of a contact portion of the film that is brought into contact with the pressing film when the pressing film presses the contact pins via the film.

According to the liquid crystal display testing device, a treatment for lowering the frictional coefficient, for example, a coating of oil, plating or the like, is provided at the contact portion of the film in respect of the pressing film, and accordingly, not only is the sliding movement of the pressing film in respect of the film smooth and the contact's performance of the contact pins in respect of the object of measurement promoted, but also wear of the film can be minimized and the pressing amount of the contact pins in respect of the object of measurement and the degree of wear of the contact pins can be made constant. Also, dust generation can be minimized.

According to another modified example of an embodiment of the present invention, a technology in which a metal film is directly attached on the film is adopted.

According to the liquid crystal display testing device, even if the film is formed by the resin film or the like which is liable to extend by absorbing moisture, the extension of the film is restrained by the metal film since the metal film is directly attached on the film. Accordingly, a pitch of the contact pins is not shifted by an extension of the film, whereby firm contact in respect of the object of measurement can be carried out.

Furthermore, a technology in which a second film is directly attached on the metal film is adopted in a modified example.

Also, the metal film can be used as a ground, whereby a design taking impedance matching up to a vicinity of a front end of the contact probe can be performed and adverse influences caused by reflection noise can be prevented even if a test is conducted in a high frequency region. That is, reflection noise is caused when a characteristic impedance between a side of substrate wirings and contact pins in the midst of a transmitting cable from a tester are not matched, and in such a case, the longer a transmitting cable having the different characteristic impedance, the larger the resulting reflection noise. The reflection noise creates a signal distortion, which is liable to cause erroneous operations at high frequencies. According to a liquid crystal display testing device of the present invention, a deviation in characteristic impedances in respect of a side of substrate wirings can be minimized up to a vicinity of front ends of the contact pins by using the metal film as a ground, whereby erroneous operations caused by reflection noise can be minimized.

Further, a technology in which a second film is directly attached on the metal film is adopted in a modified example.

According to a liquid crystal display testing device of the present invention, the second film is directly attached on the metal film, and accordingly, the effect is available in which the second film constitutes a buffer material in respect of a fastening operation in integrating the contact probes with the holding member. Accordingly, damage effected on a wiring pattern can be alleviated in the integrating operation. Also, a short-circuit of the metal film with terminals of other circuits can be prevented.

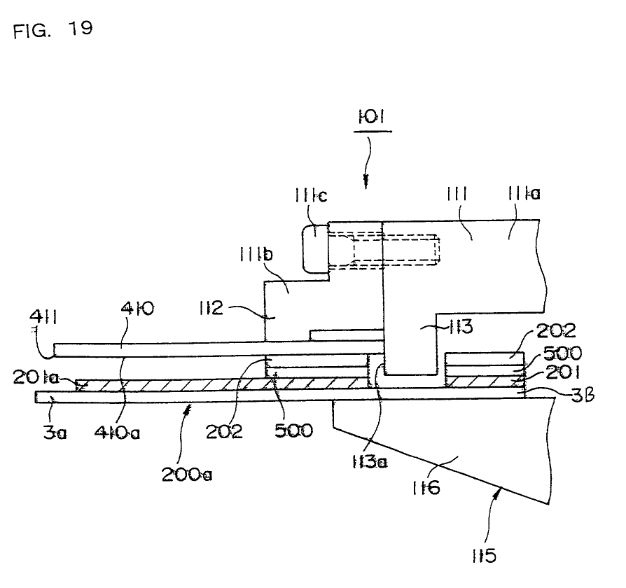

An explanation will be given of a third embodiment of a liquid crystal display testing device according to the present invention with reference to FIG. 19 through FIG. 26 as follows.

The embodiment includes a feature that an amount (length) of a projection of a highly elastic film 400 is devised in the above-described background liquid crystal display testing device. Therefore, portions the same as those explained in the background example are attached with the same notations and a detailed explanation thereof will be omitted.

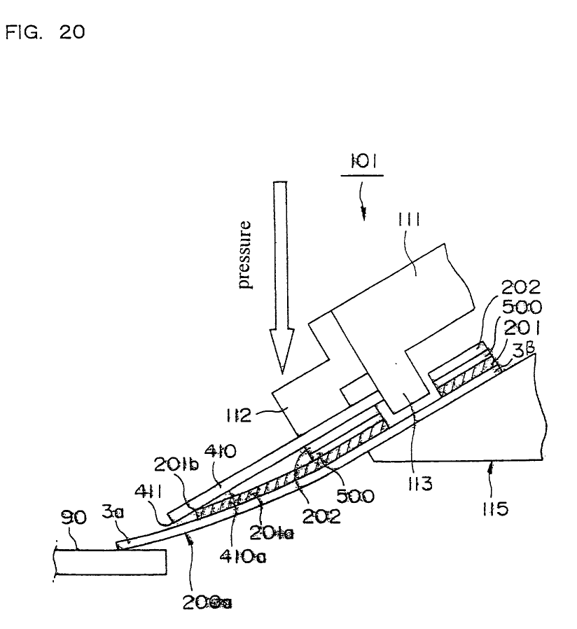

As shown in FIG. 19 and FIG. 20, according to a liquid crystal display testing device 101 of this embodiment, a highly elastic film (pressing film) 410 is installed to project from a resin film 201a such that a front end corner portion 411 thereof and the resin film 201a are not brought into contact with each other when the highly elastic film 410 presses the contact pins 3a via the resin film 201a. Further, an amount of projection of the highly elastic film 410 from the resin film 201a is set to be smaller than that of the contact pins 3a such that the highly elastic film 410 is not brought into contact with the contact pin 3a when the highly elastic film 410 presses the contact pin 3a via the resin film 201a.

The highly elastic film 410 can be constructed of an organic material or an inorganic material and it is preferable that the highly elastic film 410 is made of polyethylene terephthalate or the like in a case of an organic material and that the highly elastic film 410 is constructed of ceramics, especially a film made of alumina, in a case of an inorganic material.

Oil can be coated at a contact portion 201b of the resin film 201a with the highly elastic film 410 in order to lower the frictional coefficient, see FIG. 20.

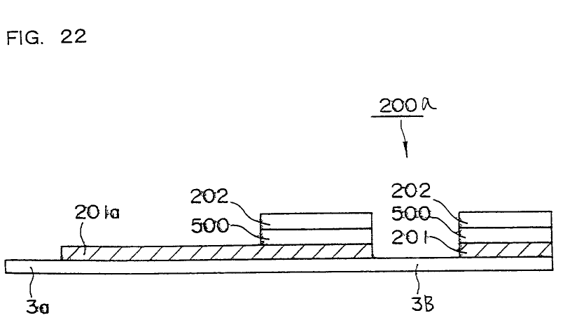

As shown in FIG. 22, a basic constitution of the contact probe 200a is provided with a structure in which pattern wirings 3B formed by a metal are attached on one-sided faces of the polyimide resin films 201 and 201a and front ends of the pattern wirings 3B are projected from end portions of the resin films 201 and 201a to constitute contact pins 3a.

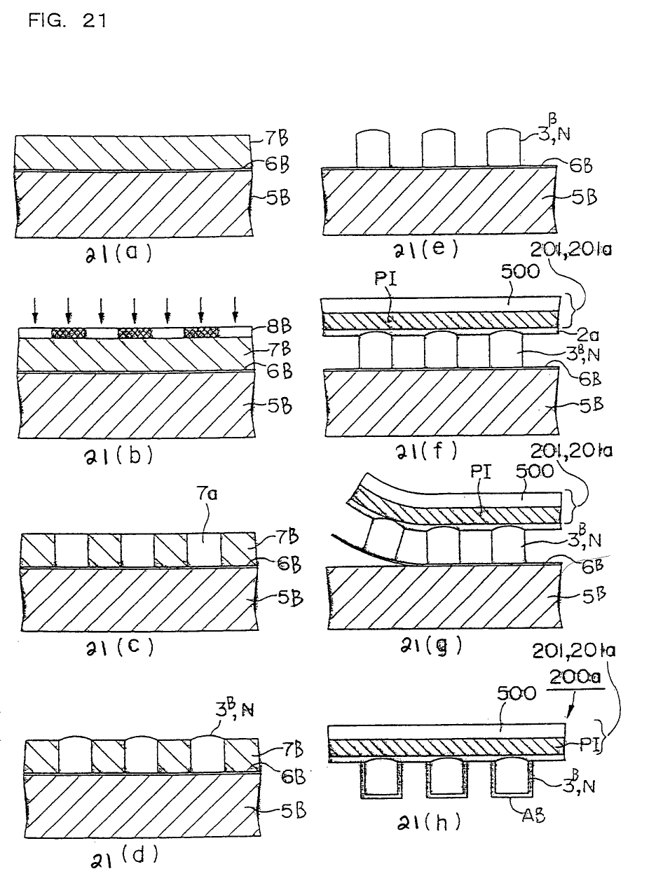

Next, an explanation will be given of the steps of fabricating the contact probe 200a in the order of steps with reference to FIGS. 21(a) through 21(h) and FIG. 22.

(Step of Forming Support Metal Plate and Base Metal Layer)

First, as shown in FIG. 21(a), a base metal layer 6B is formed on a support metal plate (substrate layer) 5B made of stainless steel by plating, e.g., Cu (copper). The base metal layer 6B is formed on the upper face of the support metal plate 5B with a uniform thickness.

(Pattern Forming Step)

Next, a photoresist layer (mask) 7B is formed on the base metal layer 6B, and thereafter, as shown in FIG. 21(b), a photomask 8B having a predetermined pattern is provided to the photoresist layer 7B, which is exposed by a photolithography technology, and as shown in FIG. 21(c), portions to constitute the pattern wirings 3B are removed by developing the photoresist layer 7B and opening portions (unmasked portion) 7a are formed on the remaining photoresist layer 7B. Although the photoresist layer 7B is formed by a negative photoresist according to the embodiment, the desired opening portions 7a may be formed by adopting a positive photoresist. Further, according to the embodiment, the photoresist layer 7B corresponds to a “mask”. However, the “mask” is not limited to one in which the opening portions 7a are formed after conducting the exposure and development steps using the photomask 8B as in the photoresist layer 7B in the embodiment. For example, the “mask” may be a film or the like in which holes have previously been perforated (that is, a state designated by notation 7B in FIG. 21(c) is formed) at portions to be subjected to plating. When such a film or the like is used as the “mask”, the pattern forming step in the embodiment is not necessary.

(Electrolytic Plating Step)

As shown in FIG. 21(d), a layer, e.g., N or Ni or an Ni alloy, to constitute the pattern wirings 3B is formed at the opening portions 7a by plating. Thereafter, as shown in FIG. 21(e), the photoresist layer 7B is removed.

(Film Adhering Step)

Next, as shown in FIG. 21(f), the resin films 201 and 201a are adhered by an adhesive agent 2a onto the Ni or Ni alloy layer N except at front ends of the pattern wirings 3B illustrated in FIG. 22, that is, portions to constitute the contact pins 3a.

The resin films 201 and 201a are constituted by a two-layer tape in which a metal film (e.g., copper foil) 500 is integrally provided to polyimide resin PI. Before the film adhering step, copper etching is carried out with respect to the copper film 500 in the two-layer tape by using a photolithography technology whereby the ground face is formed, and in carrying out the film adhering step, the resin face PI in the two layer tape is adhered on the Ni or Ni alloy layer N via the adhesive agent 2a. Incidentally, the metal film 500 may be made of Ni, an Ni alloy or the like other than the copper foil.

(Separating Step)

As shown in FIG. 21(g), a portion including the resin films 201 and 201 a, the pattern wirings 3B and the base metal layer 6B, is separated from the support metal plate 5B, and thereafter through a copper etching process, the portion is brought into a state in which only the pattern wirings 3B are adhered to the resin films 201 and 201a.

(Gold Coating Step)

As shown in FIG. 21(h), Au plating is carried out on the pattern wirings 3B in the exposed state by which an Au plating layer A is formed on the surfaces. In this case, an Au layer AB is formed on the contact pins 3a which project from the resin films 201 and 201a at a total of the surfaces over their entire peripheries.

(Second Film Adhering Step)

As shown in FIG. 22, a second resin film 202 is directly attached on the upper face of the metal film 500 by an adhesive agent.

(Oil Coating Step)

As shown in FIG. 20, oil is coated on the portion 201b at the upper face of the resin film 201a, which is brought into contact with the highly elastic film 410 in an overdriving operation.

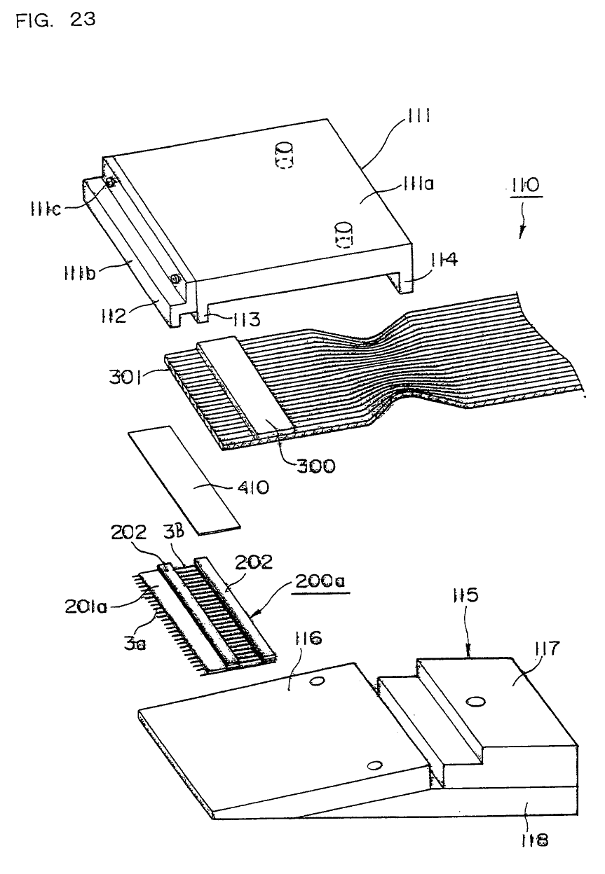

After carrying out the above-described steps, a contact probe 200a in which the pattern wirings 3B are adhered to the resin films 201 and 201a is fabricated as shown in FIG. 22 and FIG. 23.

A liquid crystal display testing device 101 according to the embodiment is provided with a structure constituted by a contact probe pinching body (holding member) 110 and a frame in a shape of a picture frame to which the contact probe pinching body is fixed.

As shown in FIG. 23, the contact probe pinching body 110 is provided with a top clamp 111 and a bottom clamp 115. The top clamp 111 is constituted by a main body portion 111a and a front end portion 111b fixed to the main body portion 111a by bolts 111c. A first projection 112 for holding the front end sides of the contact pins 3a is formed at the front end portion 111b, and a second projection 113 for holding terminals 301 on the side of a TABIC (circuit) 300 that is a driver IC and a third projection 114 for holding leads are formed at the main body portion 111a. The bottom clamp 115 is constituted by an inclined plate 116, an attaching plate 117 and a bottom plate 118.

Next, an explanation will be given of a method of integrating the contact probe pinching body 110 with reference to FIG. 19 and FIG. 23 through FIG. 25.

First, the contact probe 200a is mounted on the inclined plate 116 such that a face of the second resin film 202 is directed upwardly. Next, terminals 301 of the TABIC 300 are mounted to come in contact with the pattern wirings 3B which are disposed between the resin films 201a and 201 of the contact probe 200a (the TABIC 300 is not shown in FIG. 19 and FIG. 20). Further, both of the terminals 301 and the pattern wirings 3B are pressed by the second projection 113 of the main body portion 111a and a positioning operation is conducted by bringing the rear end face of the highly elastic film 410 into contact with a front face 113a of the second projection 113.

Next, the first projection 112 of the front end portion 111b is mounted on the highly elastic film 410 and the second resin film 202 on the front end side and the front end portion 111b is fixedly fastened to the main body portion 111a by the bolts 111c. Further, the top clamp 111 and the bottom clamp 115 are fastened by bolts 130 by which the contact probe pinching body is integrated.

An electric test of an LCD 90 using the liquid crystal display testing device 101 is carried out by inputting various testing signals by driving the TABIC 300 and taking out signals responding to the various input signals from the contact pins 3a externally via the TABIC 300, while front ends of the contact pins 3a are brought into contact with terminals (not shown) of the LCD 90.

According to the liquid crystal display testing device 101, the highly elastic film 410 is installed to project from the resin film 201a such that the front end corner portion 411 thereof and the resin film 201a are not brought into contact with each other when the highly elastic film 410 presses the contact pins 3a via the resin film 201a, and therefore the highly elastic film 410 is brought into sliding contact with the resin film 201a only at the lower face 410a thereof except at the front end corner portion 411. Accordingly, compared with a case in which the highly elastic film 410 is brought into contact with the resin film 201a at the front end corner portion 411, the contact pressure in respect of the resin film 201a is reduced in a case in which the highly elastic film 410 is brought into contact with the resin film 201a at the lower face 410a except at the front end corner portion 411, whereby wear of the resin film 201a is minimized. Accordingly, the sliding movement performance between the highly elastic film 410 and the resin film 201a in the overdriving operation is not deteriorated and the contact performance between the contact pins 3a and the terminals of the LCD 90 is not deteriorated. Also, dust generation caused by wear of the resin film 201a can be minimized.

Also, a recessed portion caused by wear is not formed on the face of the resin film 201a, and accordingly a pressing force from the highly elastic film 410 is exerted on the contact pins 3a via the resin film 201a by a predetermined pressing amount. Therefore, an amount of pressing the contact pins 3a to the terminals of the LCD 90 is not deficient, thereby to prevent contact failure from resulting. Further, for a similar reason, contact pressures of the respective contact pins 3a to the terminals are made uniform, and as a result, wear states (flatness of a pin tip) of the contact pins 3a due to repeated use are made uniform.

Furthermore, according to the liquid crystal display testing device 101, an amount of projection of the highly elastic film 410 from the resin film 201a is set to be smaller than that of the contact pins 3a such that the highly elastic film 410 is not brought into contact with the contact pins 3a when the highly elastic film 410 presses the contact pins 3a via the resin film 201a, and accordingly the highly elastic film 410 does not directly press the contact pins 3a, and the resin film 201a therebetween buffers the pressing force from the highly elastic film 410. Accordingly, even with repeated use, the contact pins 3a are not warped, bent or the like by friction between the resin film 201a and the highly elastic film 410.

Additionally, according to the liquid crystal display testing device 101, oil can be coated at the contact portion 201b of the resin film 201a in respect of the highly elastic film 410 and the coefficient of friction is lowered, and therefore not only is the sliding movement between the highly elastic film 410 and the resin film 201a smooth and is the contact performance between the contact pins 3a and the terminals of the LCD 90 promoted, but also wear of the resin film 201a can be minimized and amounts of pressing the contact pins 3a to the terminals and degrees of wear of the contact pins 3a can be made constant. Also, dust generation of the resin film 201a can be minimized.

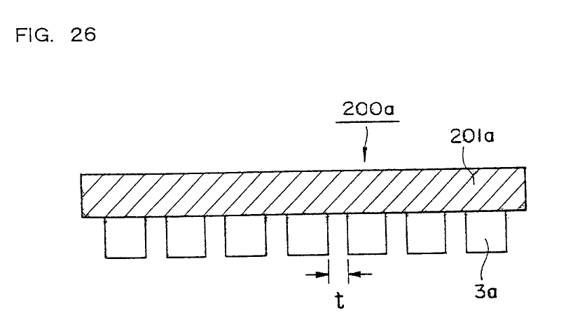

As shown in FIG. 26, although the resin films 201a and 201 are made of polyimide resin and are liable to extend by absorbing moisture, the metal film 500 is installed directly thereon, and accordingly extension of the resin films 201a and 201 is restrained by the metal film 500. Accordingly, the pitch t of the contact pins 3a is not deviated by an extension of the resin films 201a and 201, and thereby firm contact with the terminals can be carried out.

According to the liquid crystal display testing device 101, the second film 202 is directly attached on the metal film 500, and therefore an effect that the second film 202 constitutes a buffer material in respect of the fastening operation in integrating the contact probe 200a by the contact probe pinching body 110 can be achieved. Accordingly, damage caused to the wiring patterns 3B can be alleviated in the integrating operation. Further, in connecting the terminals 301 of the TABIC 300 to the contact pins 3a, a short-circuit between the metal film 500 and the terminals 301 of the TABIC 300 can be prevented since the second resin film 202 is installed on the metal film 500 that is placed on the resin film 201. Further, progress of oxidation in the atmosphere can effectively be restrained since the surface of the metal film 500 is covered by providing the second resin film 202.

Incidentally, although the embodiment is applied to a liquid crystal display testing device for an LCD, the object of measurement is not limited to an LCD but the object may be, for example, a semiconductor chip. In this case, a contact probe is cut out for measuring a semiconductor chip and a holding member (mechanical part) for measuring a semiconductor chip may be used. Further, although the embodiment is applied to a so-called probe card 101, the liquid crystal display testing device according to the present invention may be another measurement jig or the like. For example, it may be applied to sockets or the like for testing an IC chip mounted in a burn-in test device or the like of an IC chip.

Obviously, numerous additional modifications and variations of the present invention are possible in light of the above teachings. It is therefore to be understood that within the scope of the appended claims, the present invention may be practiced otherwise than as specifically described herein.

What is claimed as new and desired to be secured by Letters Patent of the United States is:

1. A contact probe for testing a liquid crystal display in which contact pins arranged in parallel are attached on one face of a first layer of a nonconductive resin film such that the contact pins are orthogonal to the first layer of the nonconductive resin film and front end portions of the contact pins are projected from the first layer of the nonconductive resin film, comprising:
a metal film further attached on the first layer of the nonconductive resin film.

2. The contact probe for testing a liquid crystal display according to claim 1, wherein the contact pins comprise a material selected from the group consisting of Ni and Ni alloy plated with Au.

3. The contact probe for testing a liquid crystal display according to claim 1, wherein the metal film comprises a material selected from the group consisting of a Ni film, a Ni alloy film, a Cu film and a Cu alloy film.

4. The contact probe for testing a liquid crystal display according to claim 1, wherein the contact pins comprise a material selected from the group consisting of Ni or a Ni alloy plated with Au, and the metal film comprises a material selected from the group consisting of a Ni film, a Ni alloy film, a Cu film and a Cu alloy film.

5. A contact probe for testing a liquid crystal display in which contact pins arranged in parallel are attached on one face of a first layer of a nonconductive resin film such that the contact pins are orthogonal to the first layer of the nonconductive resin film and front end portions of the contact pins are projected from the first layer of the nonconductive resin film, comprising:
a metal film attached on the first layer of the nonconductive resin film; and
a second layer of a nonconductive resin film attached on the metal film.

6. A contact probe for testing a liquid crystal display in which contact pins arranged in parallel are attached on one face of a first layer of a nonconductive resin film such that the contact pins are orthogonal to the first layer of the nonconductive resin film and front end portions of the contact pins are projected from the first layer of the nonconductive resin film, comprising:
a metal film attached on the first layer of the nonconductive resin film; and
an elastic film comprising an organic or an inorganic material attached on the metal film such that the elastic film is projected more shortly than the contact pins to a side where the front end portions of the contact pins are projected from the first layer of the nonconductive resin film.

7. The contact probe for testing a liquid crystal display according to claim 6, wherein the metal film comprises a material selected from the group consisting of a Ni film, a Ni alloy film, a Cu film and a Cu alloy film.

8. The contact probe for testing a liquid crystal display according to claim 6, wherein the elastic film comprising the organic or the inorganic material comprises a material selected from the group consisting of ceramics and polyethylene terephthalate.

9. A contact probe for testing a liquid crystal display in which contact pins arranged in parallel are attached on one face of a first layer of a nonconductive resin film such that the contact pins are orthogonal to the first layer of the nonconductive resin film and front end portions of the contact pins are projected from the first layer of the nonconductive resin film, comprising:
a metal film attached on the first layer of the nonconductive resin film;
a second layer of a nonconductive resin film attached on the metal film; and
an elastic film comprising an organic or an inorganic material attached on the second layer of the nonconductive resin film such that the elastic film is projected more shortly than the contact pins to a side where the front end portions of the contact pins are projected from the first layer of the nonconductive resin film.

10. A contact probe for testing a liquid crystal display in which contact pins arranged in parallel are attached on one face of a first layer of a nonconductive resin film having a first width such that the contact pins are orthogonal to the first layer of the nonconductive resin film having the first width and front end portions of the contact pins are projected from the first layer of the nonconductive resin film having the first width, comprising:
a metal film attached on the first layer of the nonconductive resin film having the first width; and
an elastic film comprising an organic or an inorganic material attached on the metal film such that the elastic film is projected more shortly than the first layer of the nonconductive resin film having the first width to a side where the front end portions of the contact pins are projected from the first layer of the nonconductive resin film having the first width, the elastic film having a second width less than the first width of the nonconductive resin film.

11. A contact probe for testing a liquid crystal display in which contact pins arranged in parallel are attached on one face of a first layer of a nonconductive resin film having a first width such that the contact pins are orthogonal to the first layer of the nonconductive resin film having the first width and front end portions of the contact pins are projected from the first layer of the nonconductive resin film having the first wide width, comprising:
a metal film attached on the first layer of the nonconductive resin film having the first width;
a second layer of a nonconductive resin film attached on the metal film; and
an elastic film comprising an organic or an inorganic material attached on the second layer of the nonconductive resin film such that the elastic film is projected more shortly than the first layer of the nonconductive resin film having the first width to a side where the front end portions of the contact pins are projected from the first layer of the nonconductive resin film having the first width, the elastic film having a second width less than the first width of the nonconductive resin film.

12. A liquid crystal display testing device comprising:
a contact probe for testing a liquid crystal display in which contact pins arranged in parallel are attached on one face of a first layer of a nonconductive resin film such that the contact pins are orthogonal to the first layer of the nonconductive resin film and front end portions of the contact pins are projected from the first layer of the nonconductive resin film and a metal film is attached on the first layer of the nonconductive resin film;
an elastic film comprising an organic or an inorganic material laminated on the metal film of the contact probe for testing a liquid crystal display such that the elastic film is projected more shortly than the contact pins;
a contact probe pinching body having a top clamp and a bottom clamp for pinching the contact probe for testing a liquid crystal display in a state in which the elastic film comprising the organic or the inorganic material is laminated on the contact probe; and
a frame fixedly supporting the contact probe pinching body.

13. The liquid crystal display testing device according to claim 12, wherein the metal film comprises a material selected from the group consisting of Ni, a Ni alloy, Cu and a Cu alloy.

14. The liquid crystal display testing device according to claim 12, wherein the elastic film comprising the organic or the inorganic material comprises a material selected from the group consisting of ceramics and polyethylene terephthalate.

15. A liquid crystal display testing device comprising:
a contact probe for testing a liquid crystal display in which contact pins arranged in parallel are attached on one face of a first layer of a nonconductive resin film such that the contact pins are orthogonal to the first layer of the nonconductive resin film and front end portions of the contact pins are projected from the first layer of the nonconductive resin film, a metal film is attached on the first layer of the nonconductive resin film and a second layer of a nonconductive resin film is attached on the metal film;
an elastic film comprising an organic or an inorganic material laminated on the second layer of the nonconductive resin film of the contact probe for testing a liquid crystal display such that the elastic film is projected more shortly than the contact pins;
a contact probe pinching body having a top clamp and a bottom clamp for pinching the contact probe for testing a liquid crystal display in a state in which the elastic film comprising the organic or the inorganic material is laminated on the contact probe; and
a frame fixedly supporting the contact probe pinching body.

16. A liquid crystal display testing device comprising:
a contact probe for testing a liquid crystal display in which contact pins arranged in parallel are attached on one face of a first layer of a nonconductive resin film having a first width such that the contact pins are orthogonal to the first layer of the nonconductive resin film having the first width and front end portions of the contact pins are projected from the first layer of the nonconductive resin film having the first width and a metal film is further attached on the first layer of the nonconductive resin film having the first width;
an elastic film comprising an organic or an inorganic material laminated on the metal film of the contact probe for testing a liquid crystal display such that the elastic film is projected more shortly than the first layer of the nonconductive resin film having the first width, the elastic film having a second width less than the first width of the nonconductive resin film;
a contact probe pinching body having a top clamp and a bottom clamp for pinching the contact probe for testing a liquid crystal display in a state in which the elastic film comprising the organic or the inorganic material is laminated on the contact probe; and
a frame fixedly supporting the contact probe pinching body.

17. A liquid crystal display testing device comprising:
a contact probe for testing a liquid crystal display in which contact pins arranged in parallel are attached on one face of a first layer of a nonconductive resin film such that the contact pins are orthogonal to the first layer of the nonconductive resin film having the first width and front end portions of the contact pins are projected from the first layer of the nonconductive resin film having the first width, a metal film is attached on the first layer of the nonconductive resin film having the first width and a second layer of a nonconductive resin film is attached on the metal film;
an elastic film comprising an organic or an inorganic material laminated on the second layer of the nonconductive resin film of the contact probe for testing a liquid crystal display such that the elastic film is projected more shortly than the first layer of the nonconductive resin film having the first width, the elastic film having a second width less than the first width of the nonconductive resin film;
a contact probe pinching body having a top clamp and a bottom clamp for pinching the contact probe for testing a liquid crystal display in a state in which the elastic film comprising the organic or the inorganic material is laminated on the contact probe; and
a frame fixedly supporting the contact probe pinching body.

18. A liquid crystal display testing device in which a contact probe for testing a liquid crystal display in which contact pins arranged in parallel are attached on one face of a first layer of a nonconductive resin film such that the contact pins are orthogonal to the first layer of the nonconductive resin film and front end portions of the contact pins are projected from the first layer of the nonconductive resin film and a metal film is attached on the first layer of the nonconductive resin film, is connected to a circuit having terminals connected to respective base ends of the contact pins, said liquid crystal display testing device comprising:
a pressing film arranged on the resin film for pressing the contact pins toward an object of measurement via the resin film when the contact pins are brought into press contact with the object of measurement;
a holding member for holding the pressing film and the contact probe; and
wherein the pressing film is installed to project from the resin film such that a front end corner portion of the pressing film is not brought into contact with the resin film when the pressing film presses the contact pins via the resin film and an amount of projection of the pressing film from the resin film is set to be smaller than an amount of projection of the contact pins from the resin film such that the pressing film is not brought into contact with the contact pins.

19. The liquid crystal display testing device according to claim 18:
wherein a treatment for lowering a coefficient of friction is carried out to a contact portion of the resin film which is brought into contact with the pressing film when the pressing film presses the contact pins via the resin film.

20. The liquid crystal display testing device according to claim 18:
wherein a second film is further attached on the metal film directly.
